(19) United States
(12) Patent Application Publication
(10) Pub. No.: US 2026/0236660 A1
(43) Pub. Date: Aug. 13, 2026

(54) SEMICONDUCTOR DEVICE MANUFACTURING APPARATUS AND SEMICONDUCTOR DEVICE MANUFACTURING METHOD

(71) Applicant: RENESAS ELECTRONICS CORPORATION, Tokyo (JP)

(72) Inventor: Norio SUGINO, Tokyo (JP)

(21) Appl. No.: 19/530,555

(22) Filed: Feb. 5, 2026

(30) Foreign Application Priority Data
Feb. 7, 2025 (JP) 2025-018965

(51) Int. Cl. G06F 30/3947

(52) U.S. Cl. CPC G06F 30/3947

(57) ABSTRACT

To provide a semiconductor device manufacturing apparatus capable of automatically placing wiring in a layout area accurately and quickly. According to one embodiment, the manufacturing device 50 for a semiconductor device includes an acquisition unit 51 that obtains a wiring cost table, which shows the wiring cost for arranging wiring above and between multiple cells placed in the layout area LA when designing a semiconductor device, classified according to multiple conditions. It also includes a selection unit 52 that selects a wiring cost from the multiple wiring costs shown in the wiring cost table based on predetermined conditions, a setting unit 53 that sets the selected wiring cost above and between each cell, and a calculation unit 54 that calculates the wiring cost of the wiring path where the wiring is arranged based on the set wiring cost.

### CROSS-REFERENCE TO RELATED APPLICATIONS

The disclosure of Japanese Patent Application No. 2025-018965 filed on February 7, 2025, including the specification, drawings and abstract is incorporated herein by reference in its entirety.

### BACKGROUND

The present disclosure relates to a manufacturing apparatus for semiconductor devices and a manufacturing method for semiconductor devices.

There are disclosed techniques listed below.

[Patent Document 1] Japanese Unexamined Patent Application Publication No. 2009-065056

Patent Document 1 discloses a layout method for semiconductor integrated circuits. The layout method of Patent Document 1 generates the layout of a semiconductor integrated circuit using cell library data.

### SUMMARY

It is desired to automatically place wiring accurately and quickly.

Other objects and novel features will become apparent from the description of this specification and the accompanying drawings.

According to one embodiment, the manufacturing apparatus for semiconductor devices includes an acquisition unit that acquires a wiring cost table, which shows wiring costs for placing wiring above and between multiple cells arranged in a layout area when designing a semiconductor device, divided according to multiple conditions; a selection unit that selects the wiring cost from the multiple wiring costs shown in the wiring cost table based on predetermined conditions; a setting unit that sets the selected wiring cost above and between each cell; and a calculation unit that calculates the wiring cost of the wiring path where the wiring is placed based on the set wiring cost.

According to one embodiment, the manufacturing method for semiconductor devices includes the steps of acquiring a wiring cost table, which shows wiring costs for placing wiring above and between multiple cells arranged in a layout area when designing a semiconductor device, divided according to multiple conditions; selecting the wiring cost from the multiple wiring costs shown in the wiring cost table based on predetermined conditions; setting the selected wiring cost above and between each cell; and calculating the wiring cost of the wiring path where the wiring is placed based on the set wiring cost.

According to the embodiment, wiring can be automatically placed in the layout area accurately and quickly.

### BRIEF DESCRIPTION OF THE DRAWINGS

FIG. 1 is a flowchart illustrating a manufacturing method for a semiconductor device according to a comparative example.

FIG. 2 is a plan view illustrating the layout area when designing a semiconductor device in the manufacturing method for a semiconductor device according to a comparative example.

FIG. 3 is a block diagram illustrating a manufacturing apparatus for a semiconductor device according to Embodiment 1.

FIG. 4 is a flowchart illustrating a manufacturing method for a semiconductor device according to Embodiment 1.

FIG. 5 is a plan view illustrating the layout area when designing a semiconductor device in the manufacturing apparatus for a semiconductor device according to Embodiment 1.

FIG. 6 is a diagram illustrating the relationship between the set values of wiring costs in the wiring cost table, the ease of wiring passage, chip size, and characteristics in the manufacturing apparatus for a semiconductor device according to Embodiment 1.

FIG. 7 is a diagram illustrating the wiring cost of wiring passing above hard macro cells, IO buffer cells, and logic cells in the absence of wiring layer specification in the manufacturing apparatus for a semiconductor device according to Embodiment 1.

FIG. 8 is a diagram illustrating the wiring cost of wiring placed between hard macro cells in the absence of wiring layer specification in the manufacturing apparatus for a semiconductor device according to Embodiment 1.

FIG. 9 is a diagram illustrating the wiring cost of wiring placed between hard macro cells and IO buffer cells in the absence of wiring layer specification in the manufacturing apparatus for a semiconductor device according to Embodiment 1.

FIG. 10 is a diagram illustrating the wiring cost of wiring placed between hard macro cells and logic cells, and between IO buffer cells and logic cells in the absence of wiring layer specification in the manufacturing apparatus for a semiconductor device according to Embodiment 1.

FIG. 11 is a diagram illustrating the wiring cost of wiring placed between hard macro cells in the presence of wiring layer specification in the manufacturing apparatus for a semiconductor device according to Embodiment 1.

FIG. 12 is a diagram illustrating the wiring cost of wiring placed between hard macro cells in the presence of wiring layer specification in the manufacturing apparatus for a semiconductor device according to Embodiment 1.

FIG. 13 is a diagram illustrating the wiring cost of wiring placed between hard macro cells and IO buffer cells in the presence of wiring layer specification in the manufacturing apparatus for a semiconductor device according to Embodiment 1.

FIG. 14 is a diagram illustrating the wiring cost of wiring placed between hard macro cells and IO buffer cells in the presence of wiring layer specification in the manufacturing apparatus for a semiconductor device according to Embodiment 1.

FIG. 15 is a diagram illustrating the wiring cost of wiring passing above hard macro cells, IO buffer cells, and logic cells selected in the case of chip size emphasis in the manufacturing apparatus for a semiconductor device according to Embodiment 1.

FIG. 16 is a diagram illustrating the wiring cost of wiring placed between hard macro cells selected in the case of chip size emphasis in the manufacturing apparatus for a semiconductor device according to Embodiment 1.

FIG. 17 is a diagram illustrating the wiring cost of wiring placed between hard macro cells and IO buffer cells selected in the case of chip size emphasis in the manufacturing apparatus for a semiconductor device according to Embodiment 1.

FIG. 18 is a diagram illustrating the wiring cost of wiring placed between hard macro cells and logic cells, and between IO buffer cells and logic cells selected in the case of chip size emphasis in the manufacturing apparatus for a semiconductor device according to Embodiment 1.

FIG. 19 is a diagram illustrating the wiring cost of wiring passing above hard macro cells, IO buffer cells, and logic cells selected in the case of emphasis on characteristics such as noise resistance in the manufacturing apparatus for a semiconductor device according to Embodiment 1.

FIG. 20 is a diagram illustrating the wiring cost of wiring placed between hard macro cells selected in the case of emphasis on characteristics such as noise resistance in the manufacturing apparatus for a semiconductor device according to Embodiment 1.

FIG. 21 is a diagram illustrating the wiring cost of wiring placed between hard macro cells and IO buffer cells selected in the case of emphasis on characteristics such as noise resistance in the manufacturing apparatus for a semiconductor device according to Embodiment 1.

FIG. 22 is a diagram illustrating the wiring cost of wiring placed between hard macro cells and logic cells, and between IO buffer cells and logic cells selected in the case of emphasis on characteristics such as noise resistance in the manufacturing apparatus for a semiconductor device according to Embodiment 1.

FIG. 23 is a diagram illustrating the start and end points of wiring in the manufacturing apparatus for a semiconductor device according to Embodiment 1.

FIG. 24 is a diagram illustrating the default values above and between each cell in the layout area in the manufacturing apparatus for a semiconductor device according to Embodiment 1.

FIG. 25 is a diagram illustrating the layout area where wiring costs are set above and between each cell in the case of chip size emphasis in the manufacturing apparatus for a semiconductor device according to Embodiment 1.

FIG. 26 is a diagram illustrating the layout area where wiring costs are set above and between each cell in the case of emphasis on characteristics such as noise resistance in the manufacturing apparatus for a semiconductor device according to Embodiment 1.

FIG. 27 is a diagram illustrating the wiring cost setting figure in the manufacturing apparatus for a semiconductor device according to Embodiment 1.

FIG. 28 is a diagram illustrating the wiring cost setting figure in the manufacturing apparatus for a semiconductor device according to Embodiment 1.

FIG. 29 is a diagram illustrating the wiring path on the layout area where wiring costs are set above and between each cell in the case of chip size emphasis in the manufacturing apparatus for a semiconductor device according to Embodiment 1.

FIG. 30 is a diagram illustrating the wiring path on the layout area where wiring costs are set above and between each cell in the case of emphasis on characteristics such as noise resistance in the manufacturing apparatus for a semiconductor device according to Embodiment 1.

FIG. 31 is a diagram illustrating the wiring path on the layout area where wiring costs are set above and between each cell in the case of emphasis on characteristics such as noise resistance in the manufacturing apparatus for a semiconductor device according to Embodiment 1.

FIG. 32 is a diagram illustrating the wiring path on the layout area where wiring costs are set above and between each cell in the case of emphasis on characteristics such as noise resistance in the manufacturing apparatus for a semiconductor device according to Embodiment 1.

### DETAILED DESCRIPTION

For clarity of explanation, the following description and drawings are appropriately omitted and simplified. In the drawings, the same elements are denoted by the same reference numerals, and a repetitive description thereof is omitted as necessary. Some reference numerals may be omitted to prevent the drawings from becoming complicated.

First, in the <Comparative Example>, the manufacturing method for a semiconductor device according to the comparative example will be described. Subsequently, in <Problems Newly Found by the Inventor>, the problems newly found by the inventor regarding the manufacturing method for the semiconductor device in the comparative example will be described. Then, in <Embodiment 1>, the manufacturing apparatus and method for the semiconductor device according to Embodiment 1 will be described in comparison with the comparative example. This clarifies the manufacturing apparatus and method for the semiconductor device according to the present embodiment. It should be noted that the comparative example and the problems newly found by the inventor are also within the scope of the technical concept of the embodiment.

### Comparative Example

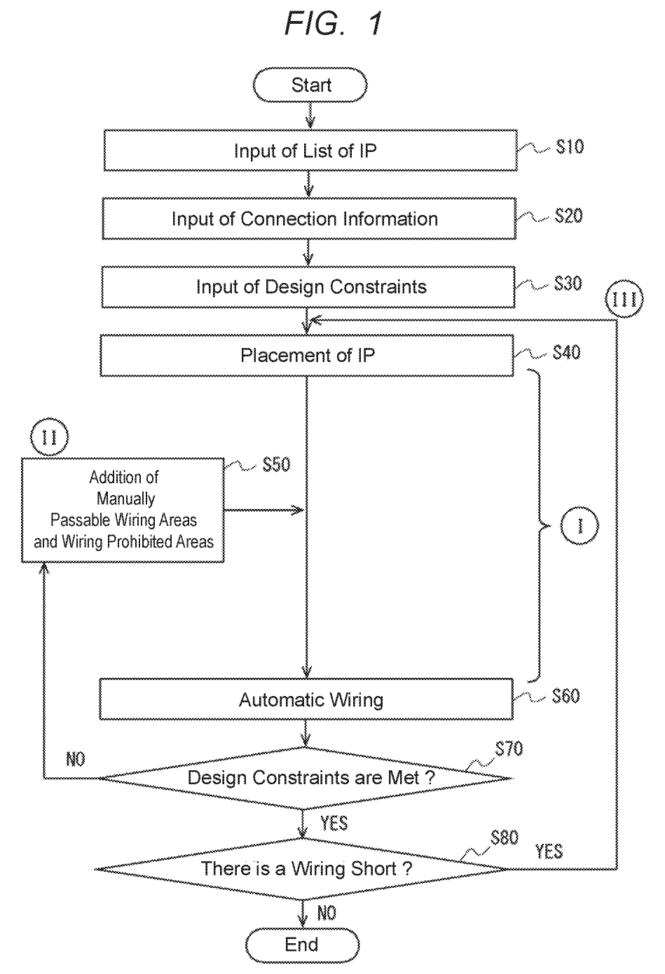

FIG. 1 is a flowchart illustrating a manufacturing method for a semiconductor device according to a comparative example. As shown in FIG. 1, the manufacturing method for a semiconductor device according to the comparative example includes steps S10 to S80. Steps S40 and S60 are also referred to as Step I. Steps S70 and S50 are also referred to as Step II. Steps S80 and S40 are also referred to as Step III.

In Step S10, the input of the list of IP (Intellectual Property) is performed. In this specification, IP is also referred to as a cell. Cells include hard macro (Hard Macro) cells, IO (Input Output) buffer cells, and logic (Logic) cells, among others. In step S20, the input of connection information is performed. In step S30, the input of design constraints is performed. Design constraints include items such as wiring resistance, wiring capacitance, EM (Electromigration), noise tolerance, and placement constraints. In step S40, the placement of IP is performed. In step S60, automatic wiring is performed. Thus, in step I, which includes step S40 and step S60, the placement of IP and automatic wiring are executed once. As a result, the impact of noise and the necessity for chip size expansion are confirmed.

In step S70, it is determined whether the design constraints are met. In step S70, if the design constraints are not met (NO), the process proceeds to step S50. In step S50, the addition of manually passable wiring areas and wiring prohibited areas is performed. Thus, in step II, which includes step S70 and step S50, when it is found that the design constraints are not met, i.e., the impact of noise or the necessity for chip size expansion is identified, the wiring path is manually specified for each wire, considering shielded wiring if necessary. Specifically, shapes or lines of the same shape as the wiring or passing points are installed on the wiring path. Furthermore, wiring prohibited areas are added as necessary. A wiring prohibited area is a shape installed in places where wiring should not pass, also known as a blockage. Subsequently, the automatic wiring of step S60 is performed again. The process of step S50 is repeatedly performed until the desired path is wired.

In step S70, if the design constraints are met (YES), the process proceeds to step S80. In step S80, it is determined whether there is a wiring short. In step S80, if there is a wiring short (YES), the process proceeds to step S40. Thus, in step III, which includes step S80 and step S40, when it is found that the wiring short cannot be resolved and a change in IP placement is necessary, the processes of step S40, step S60, and step S70 are repeated. In step S80, if there is no wiring short (NO), the process is terminated.

### Newly Identified Issues by the Inventor

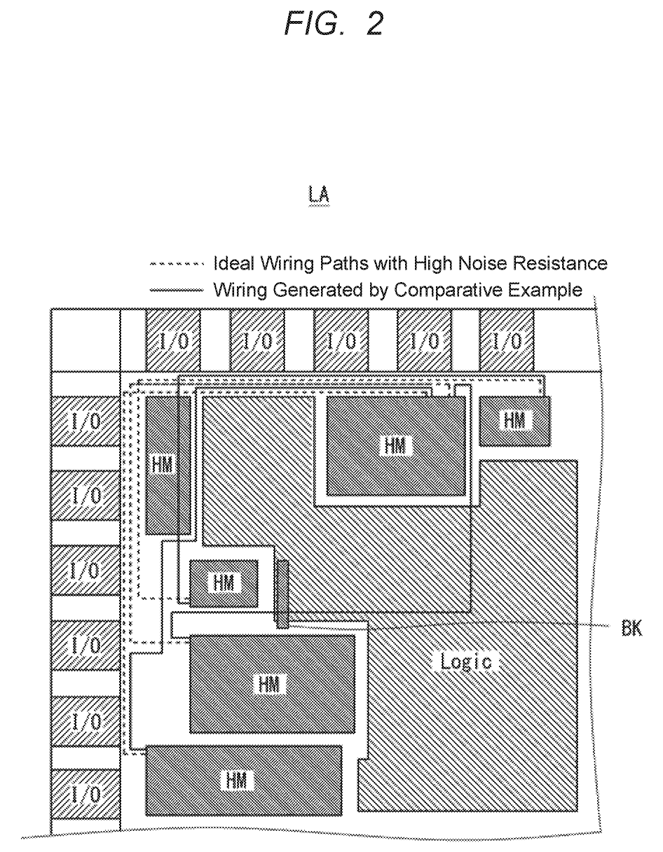

FIG. 2 is a plan view illustrating the layout area LA when designing a semiconductor device in the manufacturing method of a comparative example. As shown in FIG. 2, the layout area LA includes cells indicating design data such as IO buffer cells I/O, hard macro cells HM, and logic cells Logic. FIG. 2 also shows wiring prohibited areas (blockages) BK, ideal wiring paths with high noise resistance (dotted lines), and wiring generated by the comparative example (solid lines).

As shown in FIG. 2, the method of comparative example wires using an automatic wiring flow without specifying wiring paths. Therefore, wiring arranged by the method of the comparative example may pass through wiring prohibited areas BK and be wired at low density. For this reason, the method of the comparative example poses a risk of noise impact and a risk of chip size expansion due to wiring passage requiring a wide range. Moreover, the method of comparative example requires repeated manual review of wiring paths until the desired path is wired. Furthermore, if there is a change in the placement of IP, the method of comparative example requires re-execution of all tasks. Therefore, the workload increases.

In contrast to such a method of comparative example, it is desired to automatically place wiring accurately and quickly, considering more complex rules than humans can think of, while considering noise impact and chip size reduction, and eliminating manual work.

### Embodiment 1

Next, the manufacturing apparatus for the semiconductor device of this embodiment will be described. The manufacturing apparatus for the semiconductor device of this embodiment calculates the wiring cost for the entire semiconductor device based on the "wiring cost table" and "wiring cost setting figure" described below. Subsequently, this embodiment explores wiring paths with low wiring costs using automatic wiring tools, considering wiring layers. Therefore, it is possible to automatically achieve the handling of noise and chip size reduction, which were manually performed in the comparative example.

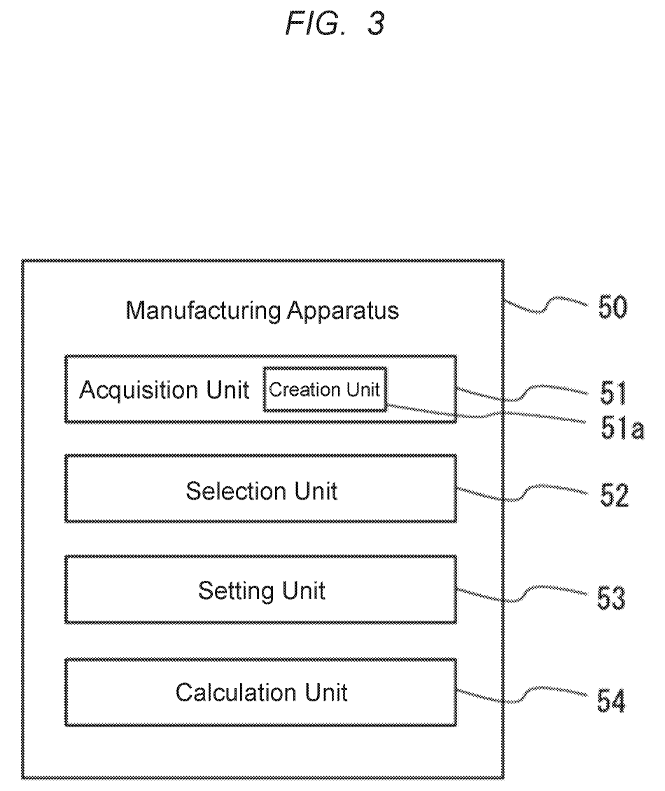

FIG. 3 is a block diagram illustrating the manufacturing apparatus 50 for the semiconductor device according to Embodiment 1. As shown in FIG. 3, the manufacturing apparatus 50 for the semiconductor device includes an acquisition unit 51, a selection unit 52, a setting unit 53, and a calculation unit 54. The acquisition unit 51 may include a creation unit 51a. The acquisition unit 51, creation unit 51a, selection unit 52, setting unit 53, and calculation unit 54 have functions as acquisition means, creation means, selection means, setting means, and calculation means.

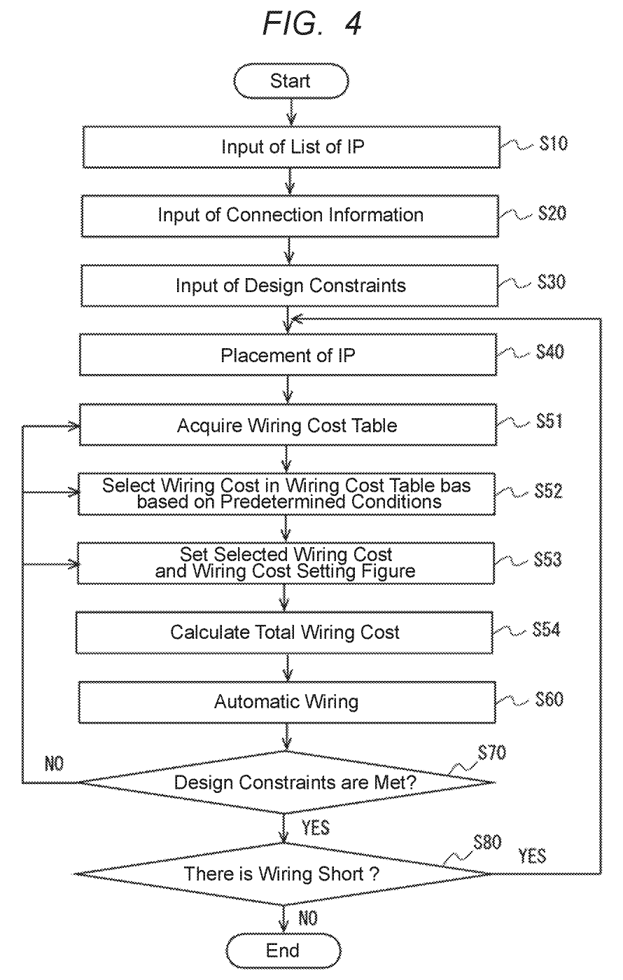

FIG. 4 is a flowchart illustrating the manufacturing method for the semiconductor device according to Embodiment 1. As shown in FIG. 4, the manufacturing method for the semiconductor device of this embodiment includes steps S51 to S54 between step S40 and step S60 of the comparative example. Step S51 is the step of acquiring the wiring cost table. Step S52 is the step of selecting the conditions of the wiring cost table. Step S53 is the step of setting the wiring cost and wiring cost setting figure. Step S54 is the step of calculating the wiring cost. Moreover, the manufacturing method for the semiconductor device of this embodiment does not include step S50 of the comparative example. As shown in FIG. 4, steps S10 to S30 are the same as in the comparative example. In step S40, the manufacturing apparatus 50 for the semiconductor device of this embodiment places IP in the layout area LA.

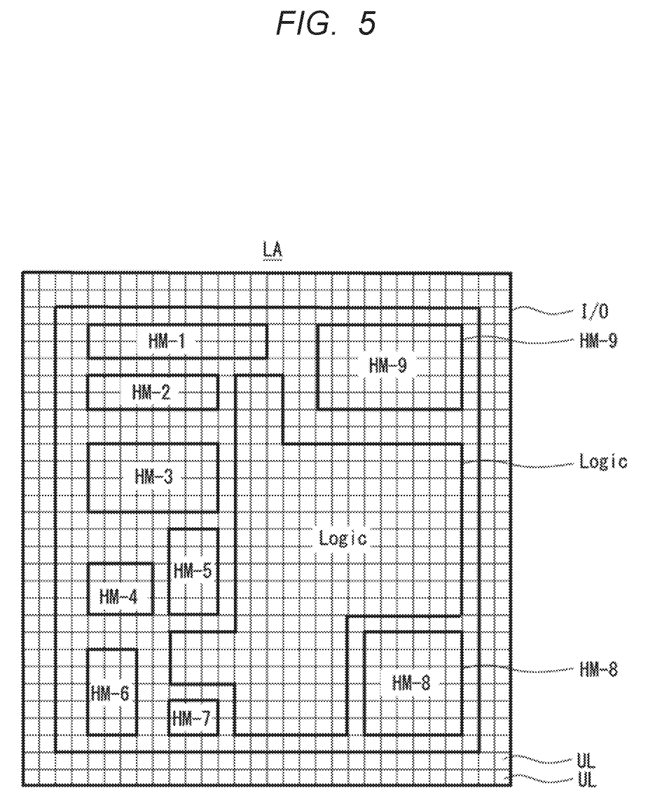

FIG. 5 is a plan view illustrating the layout area LA when designing a semiconductor device in the manufacturing apparatus 50 for the semiconductor device according to Embodiment 1. As shown in FIG. 5, the layout area LA includes multiple unit grids UL. In the figure, the symbols for some unit grids UL are omitted. The layout area LA may include unit grids UL that divide the length and width into 30 parts each, for example. A unit grid UL refers to the smallest grid that is divided for convenience when an automatic wiring tool estimates wiring paths.

Multiple cells are arranged in the layout area LA. The multiple cells include at least one of IO buffer cells I/O, hard macro cells HM-1 to 9, and logic cells Logic, for example. As shown in FIG. 2, hatching each cell makes the figure complicated, so in the following figures, the hatching of each cell is omitted. IO buffer cells I/O are arranged at the periphery of the layout area LA. Hard macro cells HM-1 to 9 and logic cells Logic are arranged inside the area surrounded by IO buffer cells I/O in the layout area LA.

Each cell arranged in the layout area LA is arranged to include at least one unit grid UL. In the figure, each cell is arranged to occupy multiple unit grids UL. Each cell arranged in the layout area LA is arranged to be adjacent to other cells with at least one unit grid UL in between. Note that some cells may be in contact. In that case, one side of any cell may be arranged to be adjacent to another cell with at least one unit grid UL in between.

As shown in FIG. 3 and FIG. 4, in step S51, the acquisition unit 51 acquires the wiring cost table. The wiring cost table is a table that shows the wiring cost for placing wiring above and between multiple cells arranged in the layout area LA when designing a semiconductor device, divided according to multiple conditions. The wiring cost table shows the wiring cost, which is an indicator of the ease of wiring passage. The wiring cost table shows the wiring cost above and between cells such as IO buffer cells I/O, hard macro cells HM-1 to 9, and logic cells Logic in the layout area LA.

When each cell arranged in the layout area LA is arranged to include multiple unit grids, the unit grids included in each cell indicate the wiring cost for placing wiring above the cell. The unit grids between each cell arranged in the layout area LA indicate the wiring cost for placing wiring between the cells.

The acquisition unit 51 may include a creation unit 51a that creates the wiring cost table. The acquisition unit 51 may acquire the wiring cost table from the creation unit 51a. Note that the acquisition unit 51 may acquire the wiring cost table from a storage unit that stores the wiring cost table. For example, the storage unit may be a storage device of the manufacturing apparatus 50 described later, or a storage device provided outside the manufacturing apparatus 50.

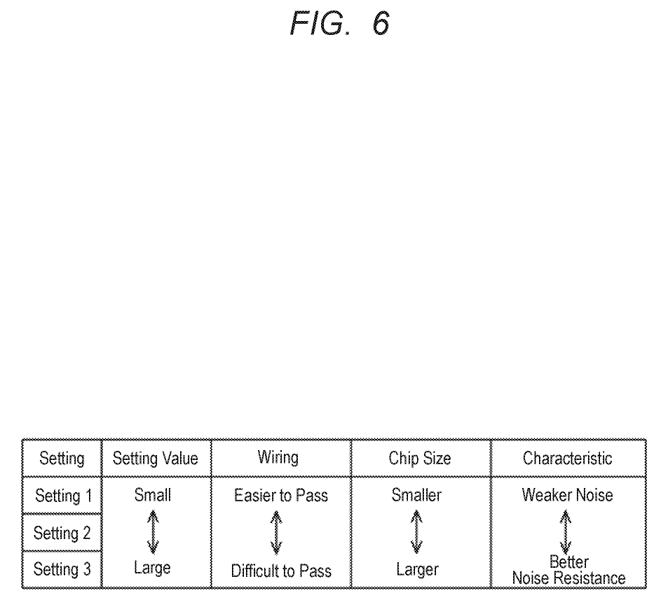

FIG. 6 is a diagram illustrating the relationship between the wiring cost setting value in the wiring cost table, the ease of wiring passage, chip size, and characteristics in the manufacturing apparatus 50 for the semiconductor device according to Embodiment 1. As shown in FIG. 6, the wiring cost table may indicate that the larger the wiring cost setting value, the more difficult it is for wiring to pass, and the smaller the setting value, the easier it is for wiring to pass. Moreover, the wiring cost table may indicate that the larger the wiring cost setting value, the larger the chip size, and the smaller the setting value, the smaller the chip size. Furthermore, the wiring cost table may indicate that the larger the wiring cost setting value, the better the noise resistance, and the smaller the setting value, the weaker the noise resistance.

The creation unit 51a may create a wiring cost table such that the larger the wiring cost, the more difficult it is for wiring to pass through, and the smaller the wiring cost, the easier it is for wiring to pass through. Additionally, the creation unit 51a may create a wiring cost table such that the larger the wiring cost, the larger the chip size, and the smaller the wiring cost, the smaller the chip size. Furthermore, the creation unit 51a may create a wiring cost table such that the larger the wiring cost, the greater the noise resistance, and the smaller the wiring cost, the smaller the noise resistance.

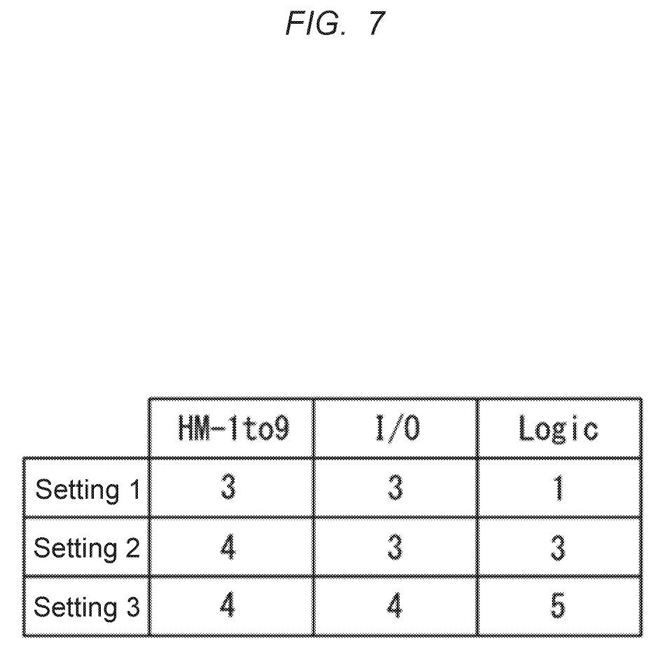

FIG. 7 is a diagram illustrating the wiring cost of wiring passing over hard macro cells HM-1 to 9, IO buffer cells I/O, and logic cells Logic in the manufacturing apparatus 50 of the semiconductor device according to Embodiment 1, in the case where no wiring layer is specified.

As shown in FIG. 7, the wiring cost for wiring passing over hard macro cells HM-1 to 9 is set to 3, 4, and 4 for settings 1, 2, and 3, respectively. The wiring cost for wiring passing over IO buffer cells I/O is set to 3, 3, and 4 for settings 1, 2, and 3, respectively. The wiring cost for wiring passing over logic cells Logic is set to 1, 3, and 5 for settings 1, 2, and 3, respectively. In this embodiment, the wiring cost is defined with five setting values ranging from 1 to 5. Additionally, for locations where no numerical specification is provided, a default value is applied.

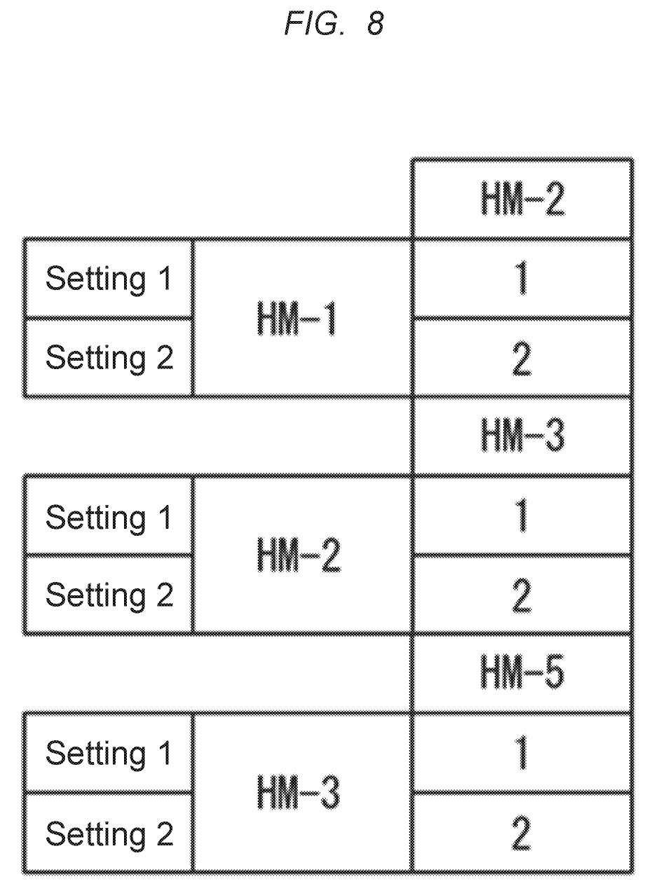

FIG. 8 is a diagram illustrating the wiring cost of wiring arranged between hard macro cells in the manufacturing apparatus 50 of the semiconductor device according to Embodiment 1, in the case where no wiring layer is specified.

As shown in FIG. 8, the wiring cost for wiring arranged between hard macro cells HM-1, 2, and 3 and hard macro cells HM-2, 3, and 5 is set to 1 and 2 for settings 1 and 2, respectively.

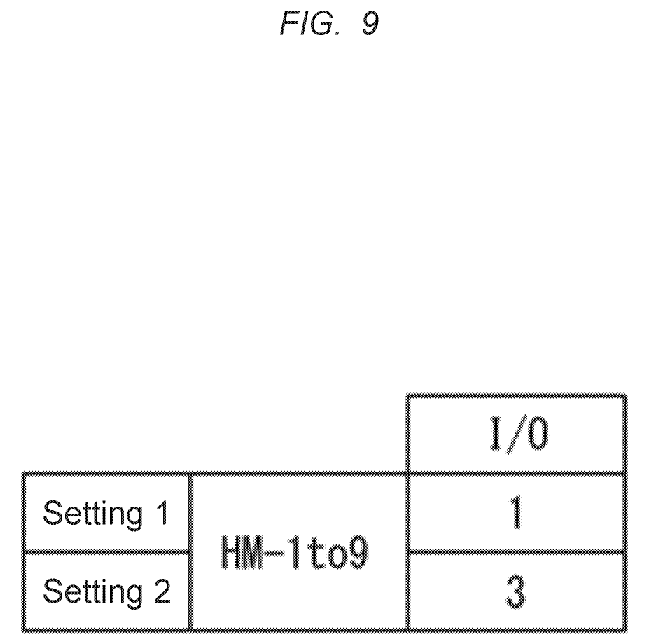

FIG. 9 illustrates the wiring cost of wiring arranged between the hard macro cells HM-1 to 9 and the IO buffer cells I/O in the manufacturing apparatus 50 of the semiconductor device according to Embodiment 1, in the case where no wiring layer is specified. As shown in FIG. 9, the wiring cost for the wiring arranged between the hard macro cells HM-1 to 9 and the IO buffer cells I/O are set to 1 and 3 for settings 1 and 2, respectively.

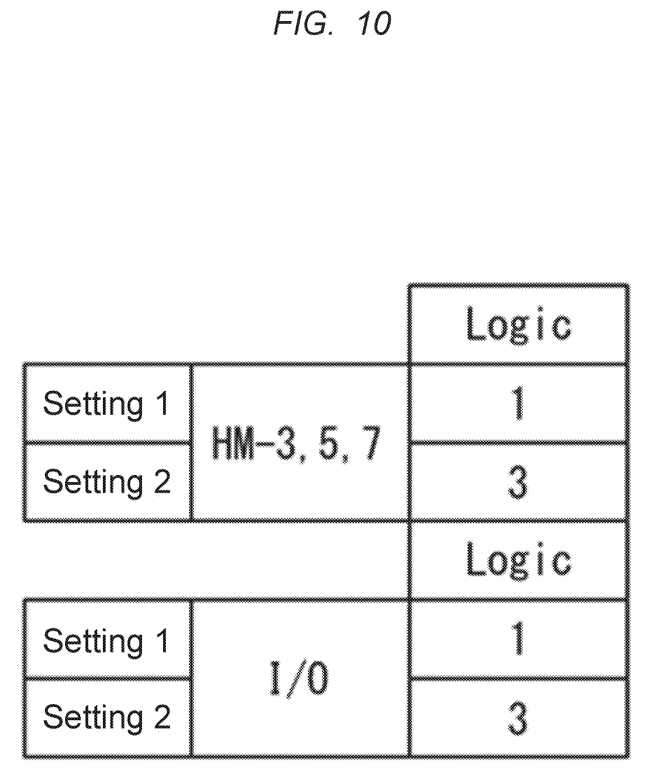

FIG. 10 illustrates the wiring cost of wiring arranged between hard macro cells and logic cells and between IO buffer cells and logic cells in the manufacturing apparatus 50 of the semiconductor device according to Embodiment 1, in case where no wiring layer is specified. As shown in FIG. 10, the wiring cost for wiring arranged between the hard macro cells HM-3, 5, 7 and the logic cells Logic, and between the IO buffer cells I/O and the logic cells Logic, is set to 1 and 3 for settings 1 and 2, respectively.

Next, the case where there is a specification for the wiring layer for wiring arranged in the layout area LA will be described.

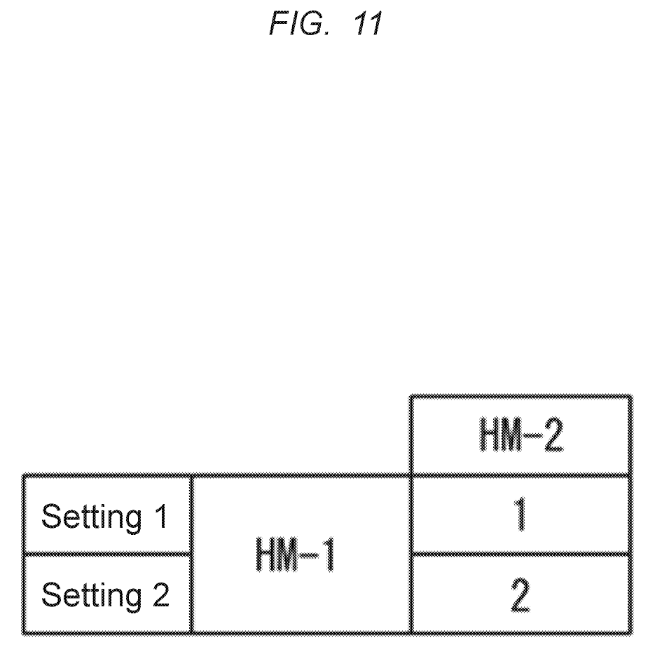

FIG. 11 illustrates the wiring cost of wiring arranged between the hard macro cells HM-1 and HM-2 in the manufacturing apparatus 50 of the semiconductor device according to Embodiment 1, in the case where there is a specification for the wiring layer. As shown in FIG. 11, if there is no setting for each wiring layer, the wiring cost for wiring arranged between the hard macro cells HM-1 and HM-2 is set to 1 and 2 for settings 1 and 2, respectively. Here, setting 1 is set to 1 for all wiring layers, and setting 2 is set to 2 for all wiring layers.

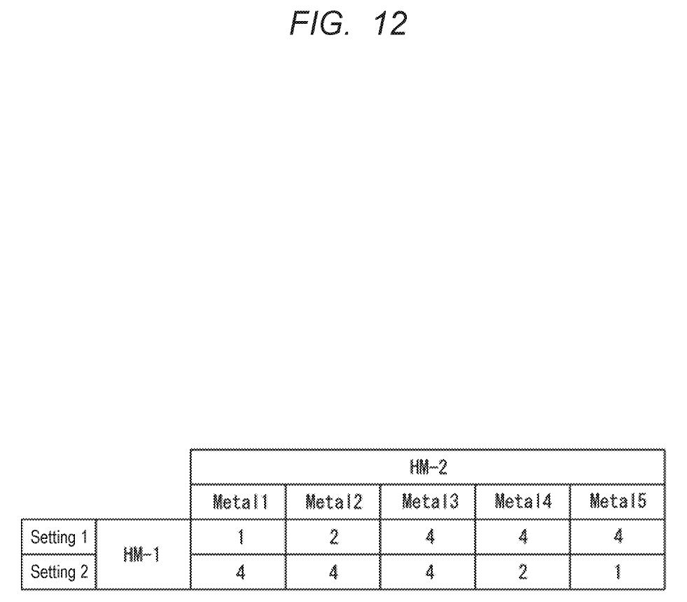

FIG. 12 is a diagram illustrating the wiring cost of wiring arranged between the hard macro cells HM-1 and HM-2 in the manufacturing apparatus 50 of the semiconductor device according to Embodiment 1, in the case where there is a specification for the wiring layer. As shown in FIG. 12, the semiconductor device includes multiple stacked wiring layers. For example, the semiconductor device may include wiring layers Metal1 to Metal5 in order from the lower layer to the upper layer. The creation unit 51a may create a wiring cost table indicating the wiring cost for each wiring layer where the wiring is arranged. When there is a setting for each wiring layer, that is, when the wiring to be arranged is selectively used for wiring layers Metal1 to Metal5 due to resistance constraints, different wiring cost settings are set for each wiring layer.

The wiring cost of wiring arranged between hard macro cells HM-1 and HM-2 on the wiring layer Meal1 is set to 1 and 4 for settings 1 and 2, respectively. The wiring cost for wiring on the wiring layer Meal2 is set to 2 and 4 for settings 1 and 2, respectively. The wiring cost for wiring on the wiring layer Meal3 is set to 4 and 4 for settings 1 and 2, respectively. The wiring cost for wiring on the wiring layer Meal4 is set to 4 and 2 for settings 1 and 2, respectively. The wiring cost for wiring on the wiring layer Meal5 is set to 4 and 1 for settings 1 and 2, respectively. Setting 1 is, for example, when you want to use lower layer wiring. This includes wiring that may have high resistance. Setting 2 is, for example, when you want to use upper layer wiring. This includes wiring that requires low resistance.

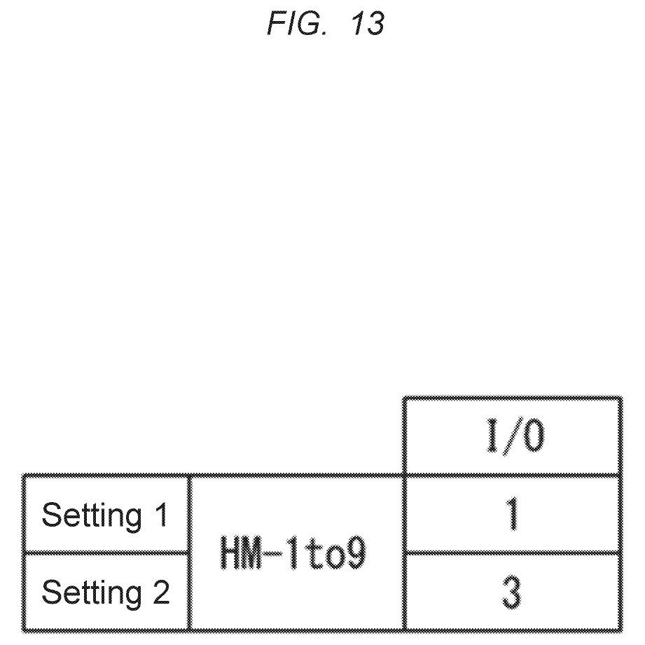

FIG. 13 is a diagram illustrating the wiring cost of wiring arranged between hard macro cells HM-1 to 9 and IO buffer cells I/O in the manufacturing apparatus 50 of the semiconductor device according to Embodiment 1, in the case where a wiring layer is specified. As shown in FIG. 13, when there is no setting for each wiring layer, the wiring cost of wiring arranged between hard macro cells HM-1 to 9 and IO buffer cells I/O are set to 1 and 3 for settings 1 and 2, respectively. Here, setting 1 is set to 1 for all layers, and setting 2 is set to 3 for all layers.

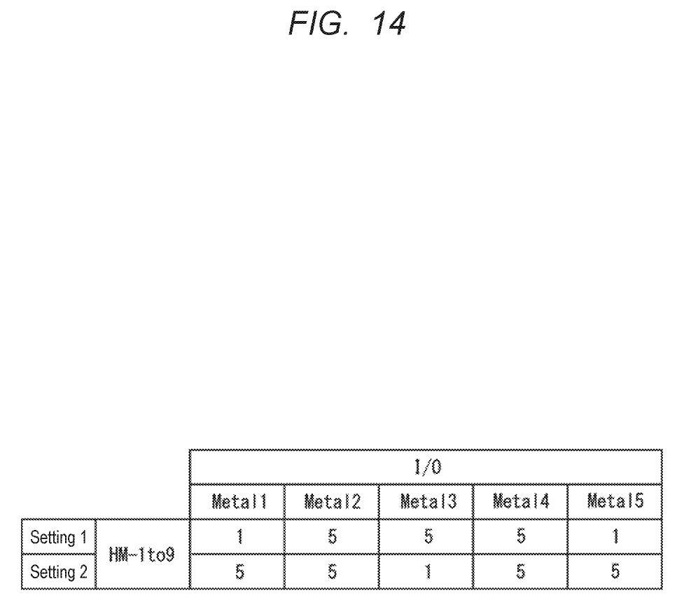

FIG. 14 is a diagram illustrating the wiring cost of wiring arranged between hard macro cells HM-1 to 9 and IO buffer cells I/O in the manufacturing apparatus 50 of the semiconductor device according to Embodiment 1, in the case where a wiring layer is specified. As shown in FIG. 14, when there is a setting for each wiring layer, that is, when the wiring to be arranged is selectively used for wiring layers Metal1 to Metal5 due to resistance constraints, different setting values are set for each wiring layer.

The wiring cost for wiring arranged between hard macro cells HM-1 to 9 and IO buffer cells I/O on the wiring layer Meal1 is set to 1 and 5 for settings 1 and 2, respectively. The wiring cost for wiring on the wiring layer Meal2 is set to 5 and 5 for settings 1 and 2, respectively. The wiring cost for wiring on the wiring layer Meal3 is set to 5 and 1 for settings 1 and 2, respectively. The wiring cost for wiring on the wiring layer Meal4 is set to 5 and 5 for settings 1 and 2, respectively. The wiring cost for wiring on the wiring layer Meal5 is set to 1 and 5 for settings 1 and 2, respectively. Setting 1 is, for example, when you want to use lower layer wiring. This includes wiring that may have high resistance. Setting 2 is, for example, when you want to use upper layer wiring. This includes wiring that requires low resistance.

In step S70, if the design constraints are not met (NO), the acquisition unit 51 may reacquire the wiring cost table. Additionally, the creation unit 51a may recreate the wiring cost table. The acquisition unit 51 may reacquire the wiring cost table for part or all of the layout area LA. The creation unit 51a may recreate the wiring cost table for part or all of the layout area LA.

Next, as shown in FIGS. 3 and 4, in step S52, the selection unit 52 selects the wiring cost in the wiring cost table based on predetermined conditions from multiple wiring costs shown in the wiring cost table. For example, the selection unit 52 selects the wiring cost based on at least one of the predetermined conditions of prioritizing chip size and noise resistance. First, the case where chip size is prioritized as a predetermined condition will be explained.

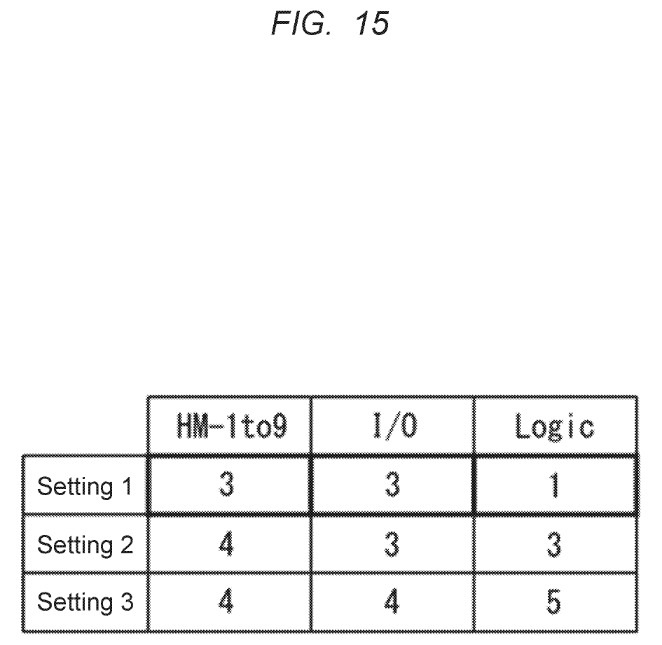

FIG. 15 is a diagram illustrating the wiring cost of wiring passing over hard macro cells HM-1 to 9, IO buffer cells I/O, and logic cells Logic selected in the case where chip size is prioritized in the manufacturing apparatus 50 of the semiconductor device according to Embodiment 1. As shown in FIG. 15, the selection unit 52 selects the wiring cost for wiring passing over hard macro cells HM-1 to 9, IO buffer cells I/O, and logic cells Logic, as the setting value of 3 for setting 1, in the case where chip size is prioritized. In this way, the selection unit 52 selects a small setting value as the wiring cost over the hard macro cells HM-1 to 9, IO buffer cells I/O, and logic cells Logic in the case where chip size is prioritized, to facilitate the arrangement of wiring over these areas.

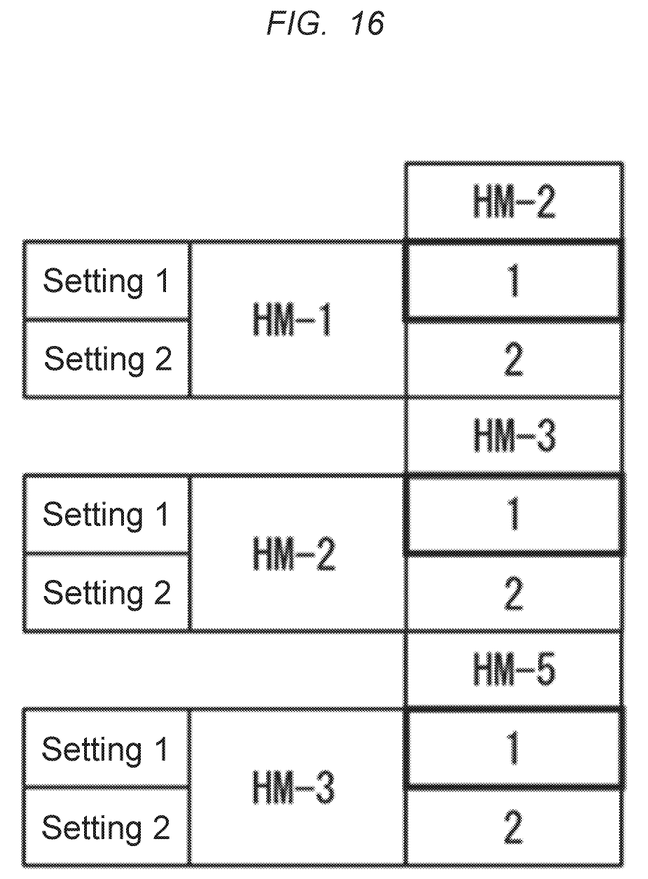

FIG. 16 is a diagram illustrating the wiring cost of wiring arranged between hard macro cells selected in the case where chip size is prioritized in the manufacturing apparatus 50 of the semiconductor device according to Embodiment 1. As shown in FIG. 16, the selection unit 52 selects the wiring cost of wiring arranged between hard macro cells as the setting value of 1 for the case where chip size is prioritized. In this way, the selection unit 52 selects a small setting value as the wiring cost between hard macro cells to facilitate the placement of wiring between hard macro cells when chip size is prioritized.

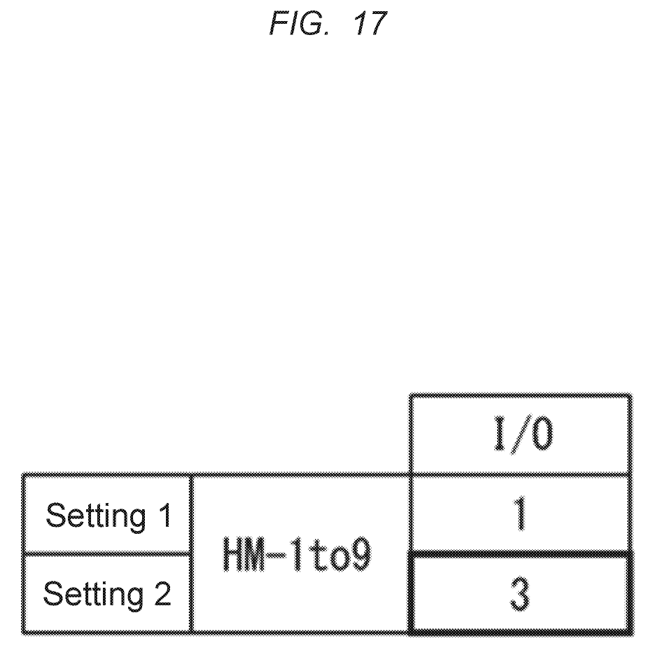

FIG. 17 illustrates the wiring cost of the wiring placed between the hard macro cells HM-1 to 9 and the IO buffer cell I/O, selected when chip size is prioritized, in the manufacturing apparatus 50 of the semiconductor device according to the Embodiment 1. As shown in FIG. 17, the selection unit 52 selects the setting value of 3 from setting 2 as the wiring cost for the wiring placed between the hard macro cells HM-1 to 9 and the IO buffer cell I/O, selected when chip size is prioritized. In this way, the selection unit 52 selects a large setting value as the wiring cost between the hard macro cells HM-1 to 9 and the IO buffer cell I/O to make it difficult to place wiring between them when chip size is prioritized.

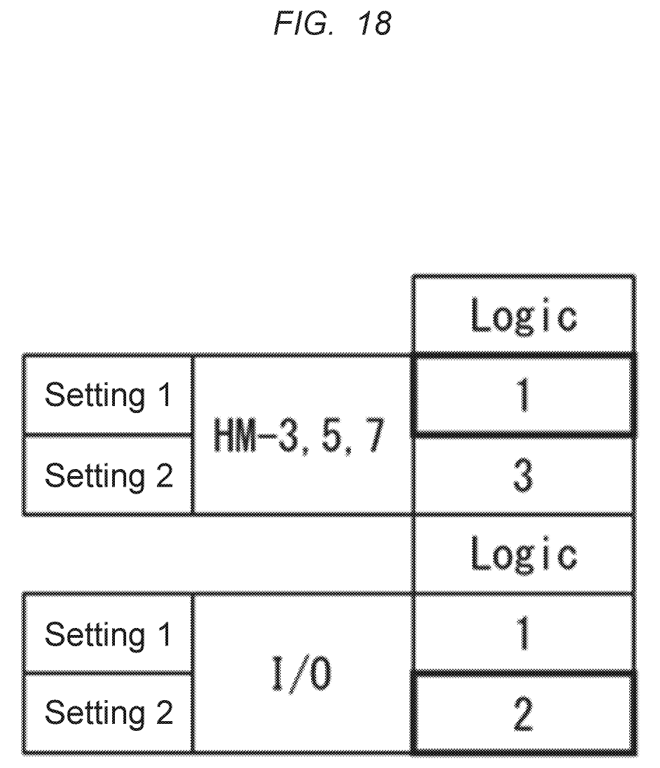

FIG. 18 illustrates the wiring cost of the wiring placed between the hard macro cells and logic cells, and between the IO buffer cells and logic cells, selected when chip size is prioritized, in the manufacturing apparatus 50 of the semiconductor device according to Embodiment 1. As shown in FIG. 18, the selection unit 52 selects the setting value of 1 from setting 1 and the setting value of 2 from setting 2 as the wiring cost for the wiring placed between the hard macro cells and logic cells, and between the IO buffer cells and logic cells, respectively. In this way, the selection unit 52 selects a small setting value as the wiring cost between the hard macro cells HM-3, 5, 7 and the logic cell Logic to facilitate the placement of wiring above the logic cell Logic when chip size is prioritized. Additionally, the selection unit 52 selects a large setting value as the wiring cost between the IO buffer cell I/O and the logic cell Logic to facilitate the placement of wiring above the logic cell Logic when chip size is prioritized.

Next, the case where characteristics such as noise resistance are prioritized will be explained as a given condition.

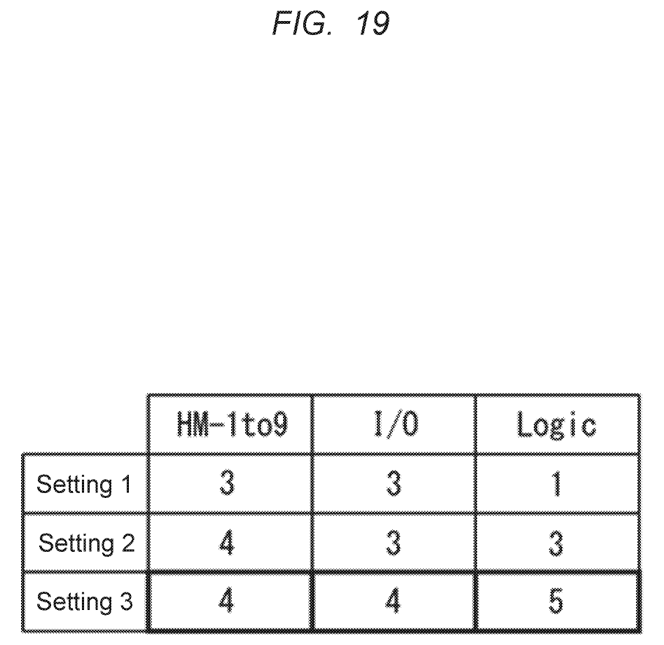

FIG. 19 illustrates the wiring cost of the wiring passing above the hard macro cells, IO buffer cells, and logic cells, selected when characteristics such as noise resistance are prioritized, in the manufacturing apparatus 50 of the semiconductor device according to Embodiment 1. As shown in FIG. 19, the selection unit 52 selects the setting value of 4 from setting 3, 4 from setting 3, and 5 from setting 3 as the wiring cost for the wiring passing above the hard macro cells HM-1 to 9, IO buffer cells I/O, and logic cells Logic, selected when characteristics such as noise resistance are prioritized. In this way, the selection unit 52 selects a large setting value as the wiring cost above the hard macro cells HM-1 to 9, the IO buffer cell I/O, and the logic cell Logic to make it difficult to place wiring above them when characteristics such as noise resistance are prioritized.

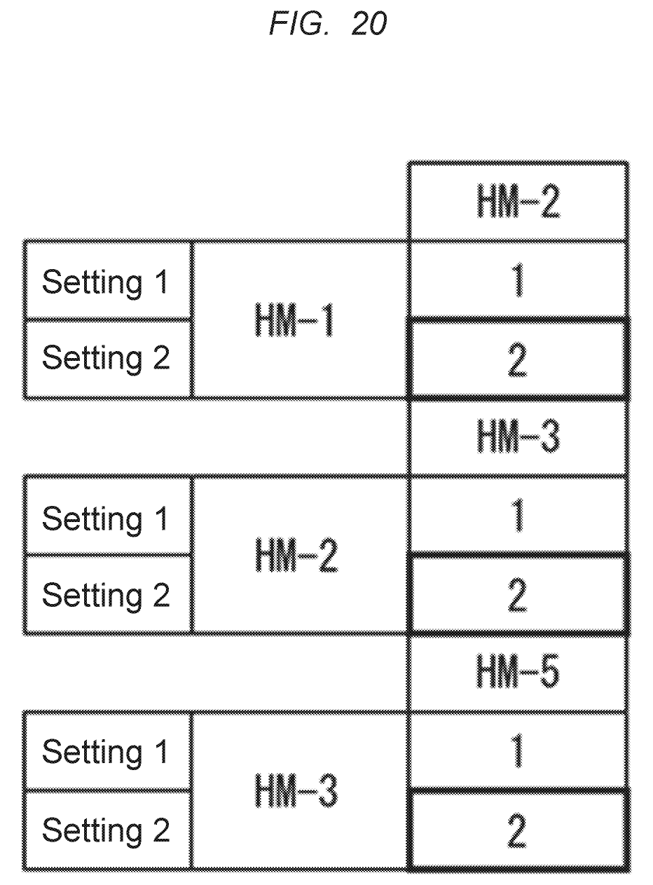

FIG. 20 illustrates the wiring cost of the wiring placed between the hard macro cells, selected when characteristics such as noise resistance are prioritized, in the manufacturing apparatus 50 of the semiconductor device according to Embodiment 1. As shown in FIG. 20, the selection unit 52 selects the setting value of 2 from setting 2 as the wiring cost of the wiring placed between the hard macro cells, selected when characteristics such as noise resistance are prioritized. In this way, the selection unit 52 selects a large setting value as the wiring cost between the hard macro cells to make it difficult to place wiring between the hard macro cells when characteristics such as noise resistance are prioritized.

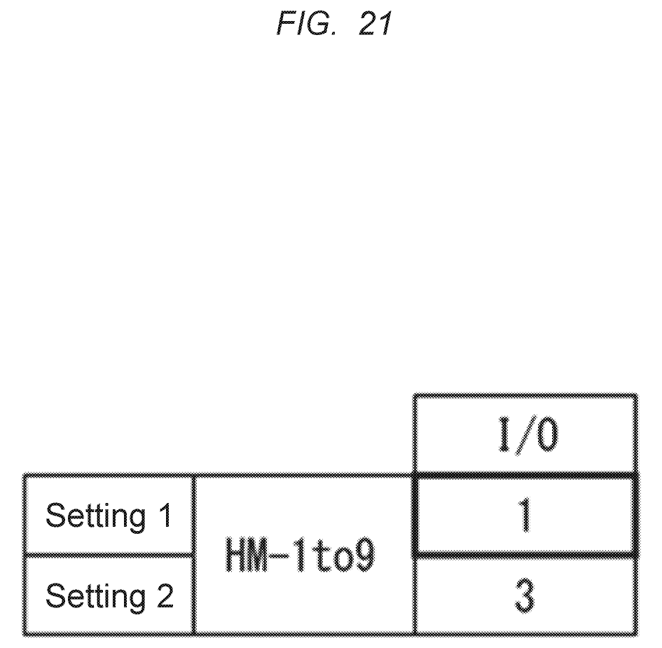

FIG. 21 illustrates the wiring cost of the wiring placed between the hard macro cells and the IO buffer cells, selected when characteristics such as noise resistance are prioritized, in the manufacturing apparatus 50 of the semiconductor device according to Embodiment 1. As shown in FIG. 21, the selection unit 52 selects the setting value of 1 from setting 1 as the wiring cost for the wiring placed between the hard macro cells HM-1 to 9 and the IO buffer cell I/O, selected when characteristics such as noise resistance are prioritized. In this way, the selection unit 52 selects a large setting value as the wiring cost between the hard macro cells HM-1 to 9 and the IO buffer cell I/O to make it difficult to place wiring between the hard macro cells HM-1 to 9 and the IO buffer cell I/O when characteristics such as noise resistance are prioritized.

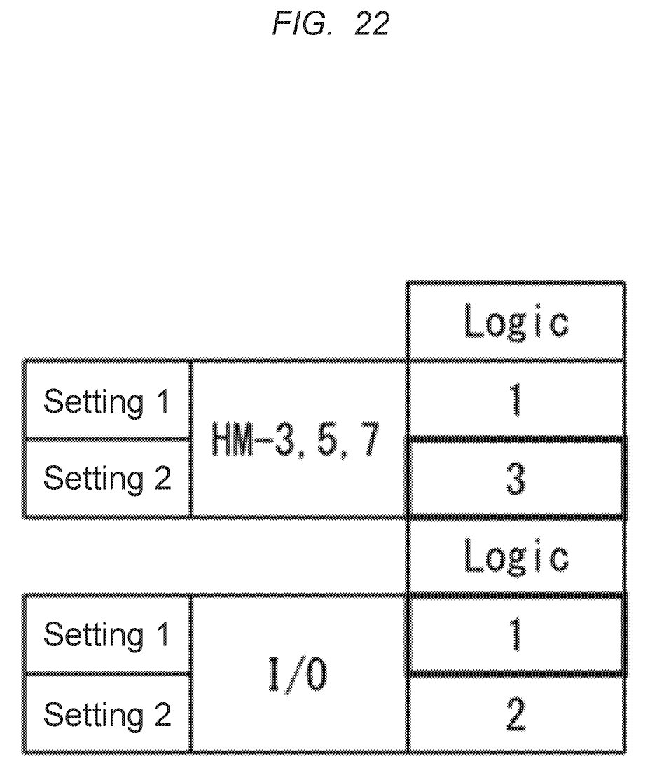

FIG. 22 illustrates the wiring cost of the wiring placed between the hard macro cells and logic cells, and between the IO buffer cells and logic cells, selected when characteristics such as noise resistance are prioritized, in the manufacturing apparatus 50 of the semiconductor device according to Embodiment 1. As shown in FIG. 22, the selection unit 52 selects the setting value of 3 from setting 2 and the setting value of 1 from setting 1 as the wiring cost for the wiring placed between the hard macro cells and logic cells, and between the IO buffer cells and logic cells, respectively. In this way, the selection unit 52 selects a large setting value as the wiring cost between the hard macro cells HM-3, 5, 7 and the logic cell Logic to make it difficult to place wiring above the logic cell Logic when characteristics such as noise resistance are prioritized. Additionally, the selection unit 52 selects a small setting value as the wiring cost between the IO buffer cell I/O and the logic cell Logic to facilitate the placement of wiring above the logic cell Logic when characteristics such as noise resistance are prioritized.

In step S70, if the design constraints are not met (NO), the selection unit 52 may reselect the wiring cost based on predetermined conditions from the multiple wiring costs shown in the wiring cost table. The selection unit 52 may reselect the wiring cost from the wiring cost table re-acquired by the acquisition unit 51. Additionally, the selection unit 52 may reselect a different wiring cost from the same wiring cost table as before. The selection unit 52 may also reselect the wiring cost for some or all of the unit grids UL in the layout area LA.

Next, as shown in FIGS. 3 and 4, in step S53, the setting unit 53 sets the selected wiring cost above each cell and between each cell. First, set the starting point LS and the endpoint LE of the wiring.

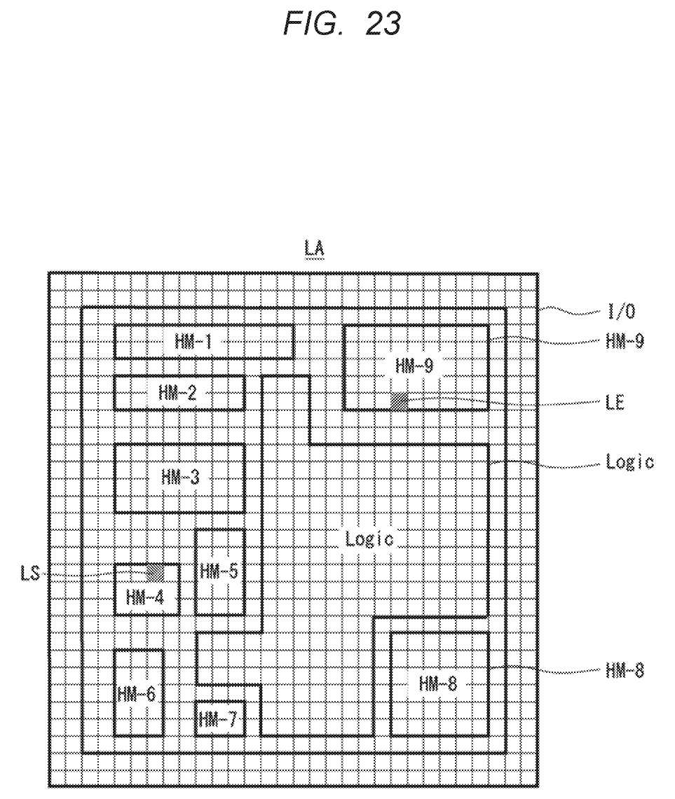

FIG. 23 illustrates the starting point LS and the endpoint LE of the wiring in the manufacturing apparatus 50 of the semiconductor device according to Embodiment 1. As shown in FIG. 23, the setting unit 53 places the starting point LS and the endpoint LE of the wiring in the layout area LA. For example, the setting unit 53 sets a part of the hard macro cell HM-4 as the starting point LS and a part of the hard macro cell HM-9 as the endpoint LE. Note that the setting unit 53 may set the starting point LS and the endpoint LE of the wiring after setting the default values or wiring costs in the unit grids UL between and above each cell in the layout area LA.

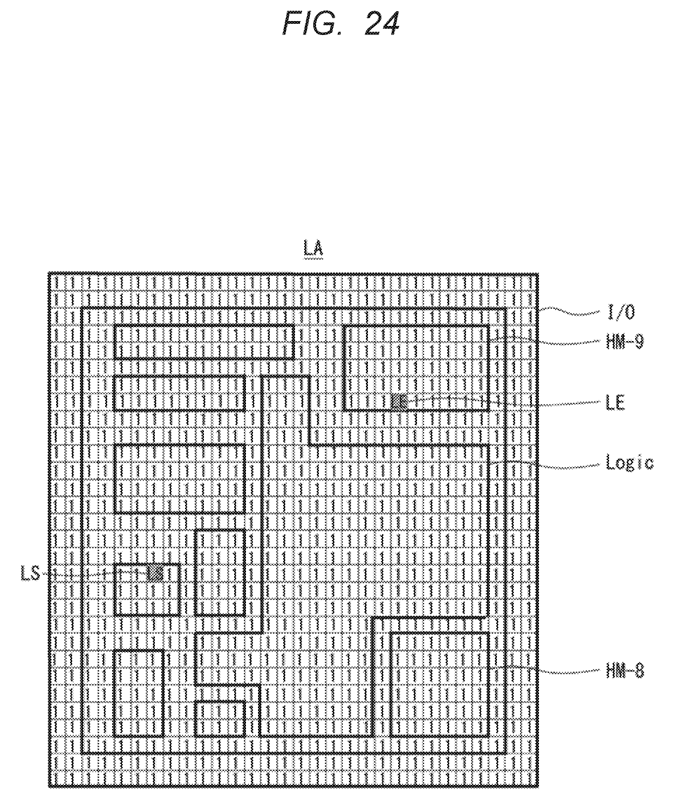

FIG. 24 illustrates the default values above each cell and between each cell in the layout area LA in the manufacturing apparatus 50 of the semiconductor device according to Embodiment 1. As shown in FIG. 24, the default value above each cell and between each cell in the layout area LA may be 1. In this way, the setting unit 53 may set default values in the unit grid UL in the layout area LA in advance. The default value of each unit grid in the layout area LA may be any setting value determined for each automatic wiring tool from the range of values from the minimum to the maximum wiring cost that can be set by the automatic wiring tool.

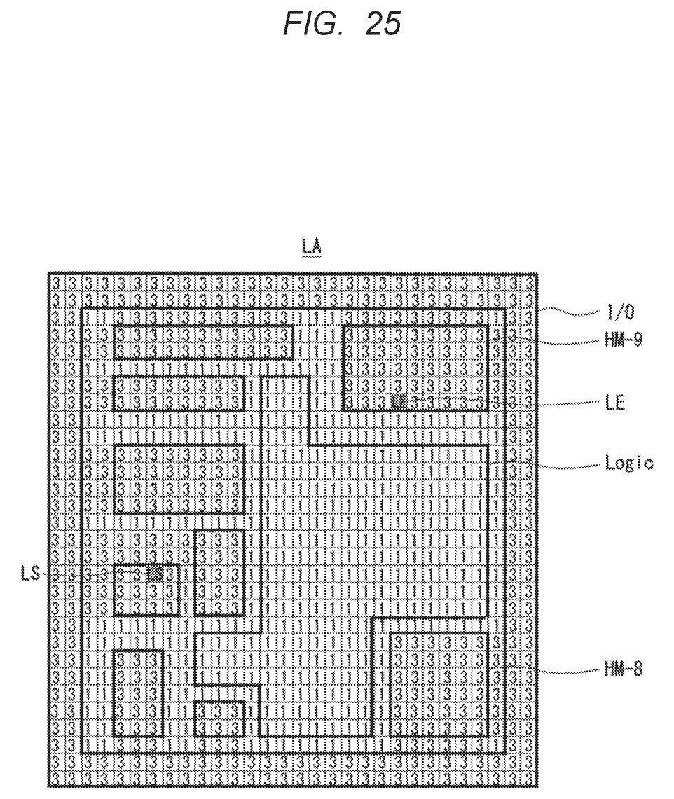

FIG. 25 illustrates the layout area LA where the wiring cost is set above each cell and between each cell in the case where chip size is prioritized in the manufacturing apparatus 50 of the semiconductor device according to Embodiment 1. As shown in FIG. 25, the setting unit 53 sets the wiring cost above each cell and between each cell. The setting unit 53 sets the selected wiring cost in each unit grid UL in the layout area LA. The setting unit 53 may overwrite the default values with the selected wiring costs in each unit grid UL above and between the multiple cells placed in the layout area LA.

For example, the setting unit 53 sets the selected values for the wiring cost above each cell and between each cell when chip size is prioritized. Specifically, the setting unit 53 sets the wiring cost of the wiring passing above the hard macro cells HM-1 to 9, the IO buffer cell I/O, and the logic cell Logic as the setting value of 3 from setting 1, 3 from setting 1, and 1 from setting 1, respectively. The setting unit 53 sets the setting value of 1 from setting 1 as the wiring cost for the wiring placed between the hard macro cells. The setting unit 53 sets the setting value of 3 from setting 2 as the wiring cost for the wiring placed between the hard macro cells HM-1 to 9 and the IO buffer cell I/O. The setting unit 53 sets the setting value of 1 from setting 1 and the setting value of 3 from setting 2 as the wiring cost for the wiring placed between the hard macro cells HM-3, 5, 7 and the logic cell Logic, and between the IO buffer cell I/O and the logic cell Logic, respectively.

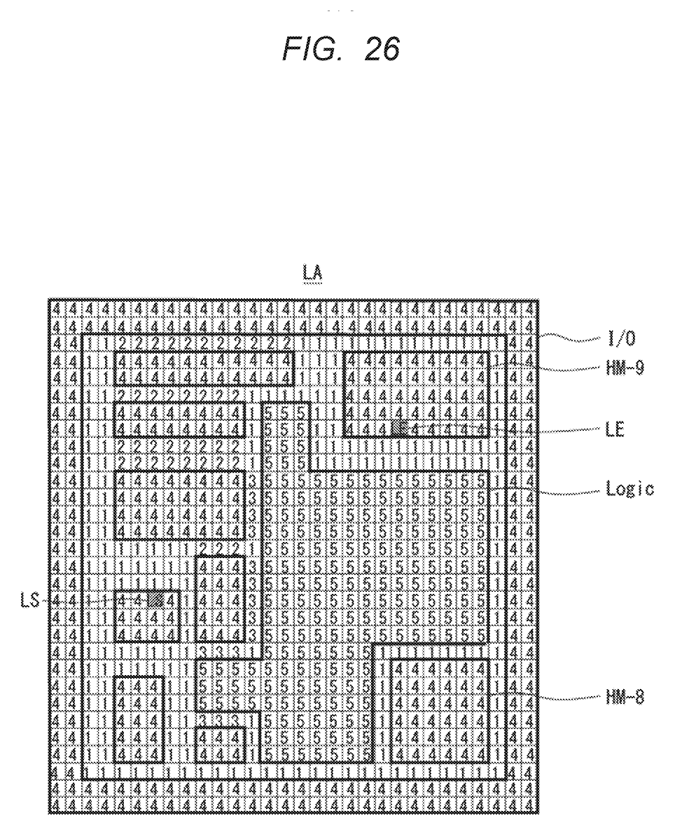

FIG. 26 illustrates the layout area LA where the wiring cost is set above each cell and between each cell in the case where characteristics such as noise resistance are prioritized, in the manufacturing apparatus 50 of the semiconductor device according to Embodiment 1. As shown in FIG. 26, even in this case, the setting unit 53 sets the wiring cost above each cell and between each cell. The setting unit 53 sets the wiring cost selected for noise resistance and other characteristics in each unit grid UL in the layout area LA. The setting unit 53 may overwrite the selected wiring cost with the default value for each unit grid UL above and between the multiple cells arranged in the layout area LA.

The setting unit 53 sets the wiring cost for the wiring passing above the hard macro cells HM-1 to 9, IO buffer cells I/O, and logic cells Logic as 4, 4, and 5, which are the setting values of setting 3, respectively. The setting unit 53 sets the wiring cost for the wiring arranged between hard macro cells as 2, which is the setting value of setting 2. The setting unit 53 sets the wiring cost for the wiring arranged between hard macro cells HM-1 to 9 and IO buffer cells I/O as 1, which is the setting value of setting 1. The setting unit 53 sets the wiring cost for the wiring arranged between hard macro cells HM-3, 5, 7 and logic cells Logic, and between IO buffer cells I/O and logic cells Logic, as 3, which is the setting value of setting 2, and 1, which is the setting value of setting 1, respectively.

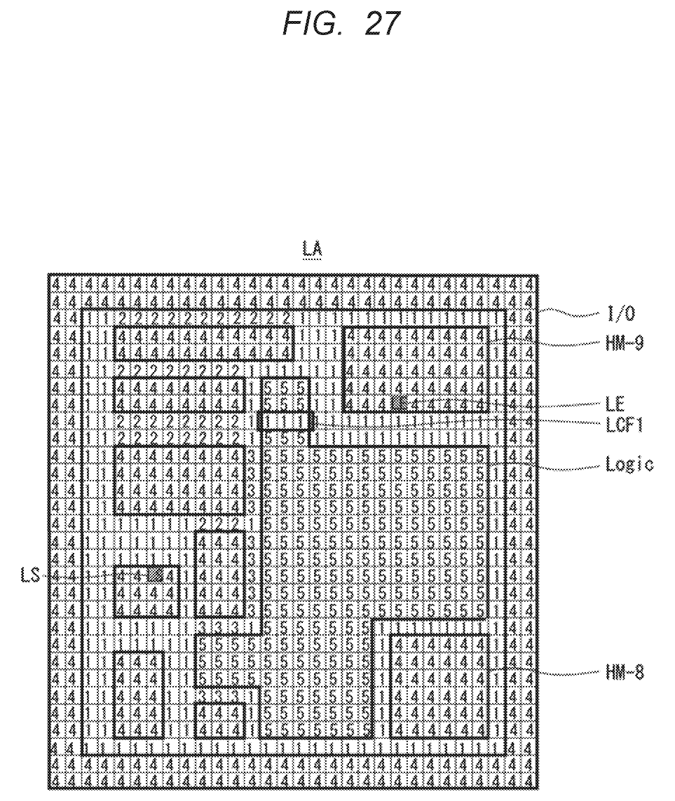

FIG. 27 is a diagram illustrating the wiring cost setting figure LCF1 in the manufacturing apparatus 50 of the semiconductor device according to Embodiment 1. As shown in FIG. 27, the setting unit 53 may arrange the wiring cost setting figure LCF1. Specifically, the setting unit 53 may superimpose and set the wiring cost setting figure LCF1 in the layout area LA after setting the wiring cost selected by the selection unit 52 above and between the multiple cells in the layout area LA. The wiring cost setting figure LCF1 includes a figure indicating partial relaxation to facilitate wiring arrangement. The wiring cost setting figure LCF1 reduces the wiring cost of the unit grid UL in the arranged layout area LA. Therefore, the setting unit 53 arranges the wiring cost setting figure LCF1 at the location where wiring is desired. In this way, the setting unit 53 sets a small setting value as the wiring cost for the unit grid UL in the part where the wiring cost setting figure LCF1 is arranged. In the figure, the setting unit 53 sets 1 as the wiring cost above a part of the logic cells Logic. The setting unit 53 forcibly overwrites the wiring cost set based on the wiring cost table with the setting value 1 assigned to the wiring cost setting figure LCF1.

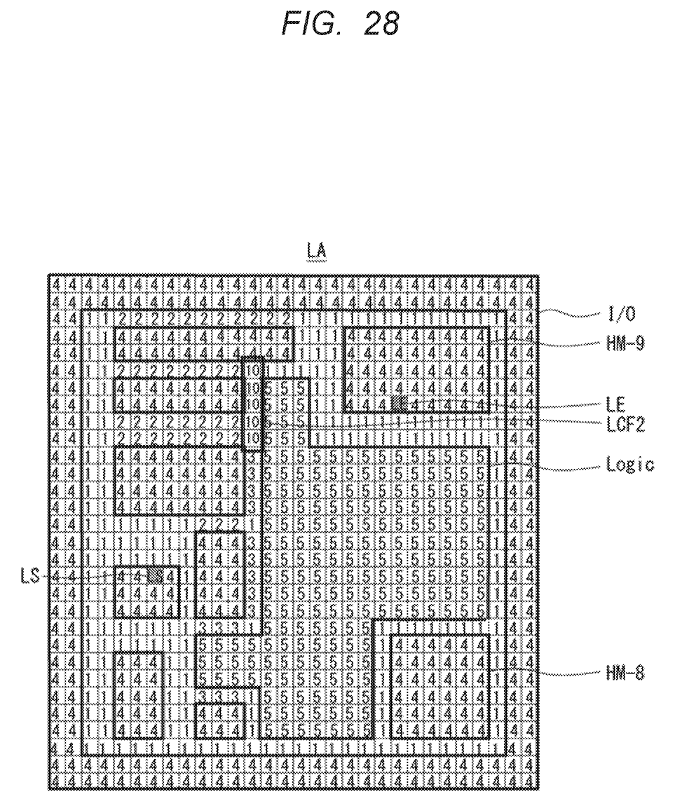

FIG. 28 is a diagram illustrating the wiring cost setting figure LCF2 in the manufacturing apparatus 50 of the semiconductor device according to Embodiment 1. As shown in FIG. 28, the setting unit 53 may set the wiring cost setting figure LCF2. Specifically, the setting unit 53 may superimpose and set the wiring cost setting figure LCF2 in the layout area LA after setting the wiring cost selected by the selection unit 52 above and between the multiple cells in the layout area LA. The wiring cost setting figure LCF2 includes a figure indicating partial reinforcement to make wiring arrangement difficult. The wiring cost setting figure LCF2 increases the wiring cost of the unit grid UL in the arranged layout area LA. Therefore, the setting unit 53 arranges the wiring cost setting figure LCF2 at the location where wiring is not desired. In this way, setting unit 53 sets a large setting value as the wiring cost for the unit grid UL in the part where the wiring cost setting figure LCF2 is arranged. In the figure, the setting unit 53 sets 10 as the wiring cost between hard macro cells HM-1 to 3 and the logic cells Logic. The setting unit 53 forcibly overwrites the wiring cost set based on the wiring cost table with the setting value 10 assigned to the wiring cost setting figure LCF2.

In step S70, if the design constraints are not satisfied (NO), the setting unit 53 may reset the wiring cost selected by the selection unit 52 to a predetermined location in the layout area LA. The setting unit 53 may reset the wiring cost for a predetermined unit grid UL in the layout area LA.

Next, in step S54, as shown in FIGS. 3 and 4, calculation unit 54 calculates the total wiring cost of the wiring path where the wiring is arranged. The wiring path includes the unit grid UL in the layout area LA. The starting point LS of the wiring includes the unit cell UL. The wiring endpoint LE includes a unit grid. The wiring path is a path where multiple unit grids UL are connected from the starting point LS corresponding to the wiring to the endpoint LE. The calculation unit 54 may select one wiring path from multiple wiring paths connecting the starting point LS to the endpoint LE based on predetermined conditions. The calculation unit 54 sums the wiring costs of the unit grids UL along the wiring path from the starting point LS to the endpoint LE. The calculation unit 54 may select the wiring path with the minimum total wiring cost as the path to be implemented. For example, the calculation unit 54 may select the wiring path with the smallest total wiring cost.

In step S70, if the design constraints are not satisfied (NO), the calculation unit 54 may calculate the total wiring cost of the wiring path based on the wiring cost reset by the setting unit 53. Additionally, the calculation unit 54 may select the wiring path to be actually implemented from the wiring paths arranged by automatic wiring based on the wiring cost set in the layout area LA.

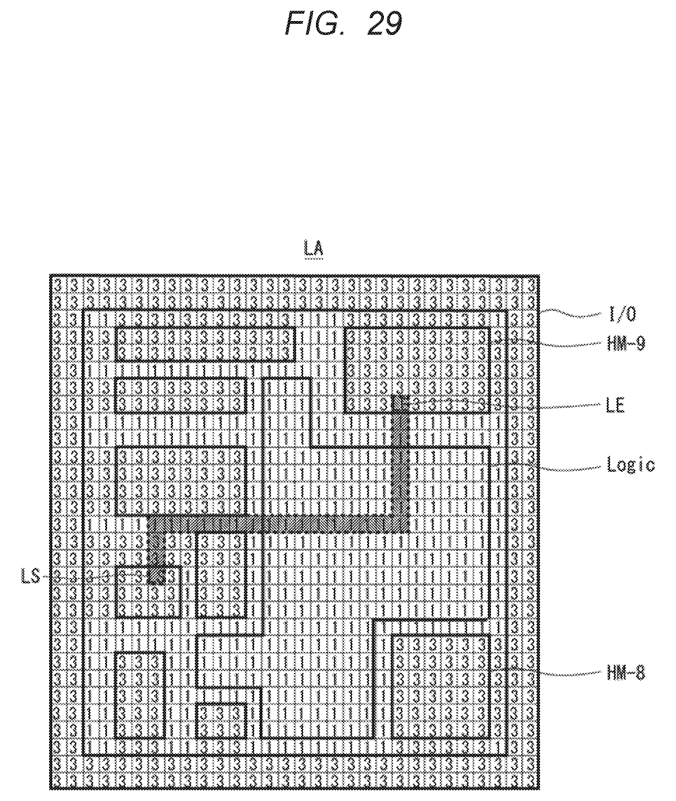

FIG. 29 is a diagram illustrating the wiring path on the layout area LA where the wiring cost is set above and between each cell in the case of chip size priority in the manufacturing apparatus 50 of the semiconductor device according to Embodiment 1. As shown in FIG. 29, calculation unit 54 calculates the wiring cost of the automatically wired wiring path, for example. In the figure, the wiring cost setting figures LCF1 and LCF2 are not set.

The calculation unit 54 sums the wiring costs of the unit grids UL along the wiring path from the starting point LS to the endpoint LE. In the case of chip size priority, the wiring path becomes the shortest path passing above the logic cells Logic. Therefore, the wiring path is the shortest route passing over the logic cell Logic. The calculation unit 54 may select the wiring path that implements the wiring route with the minimum total wiring cost.

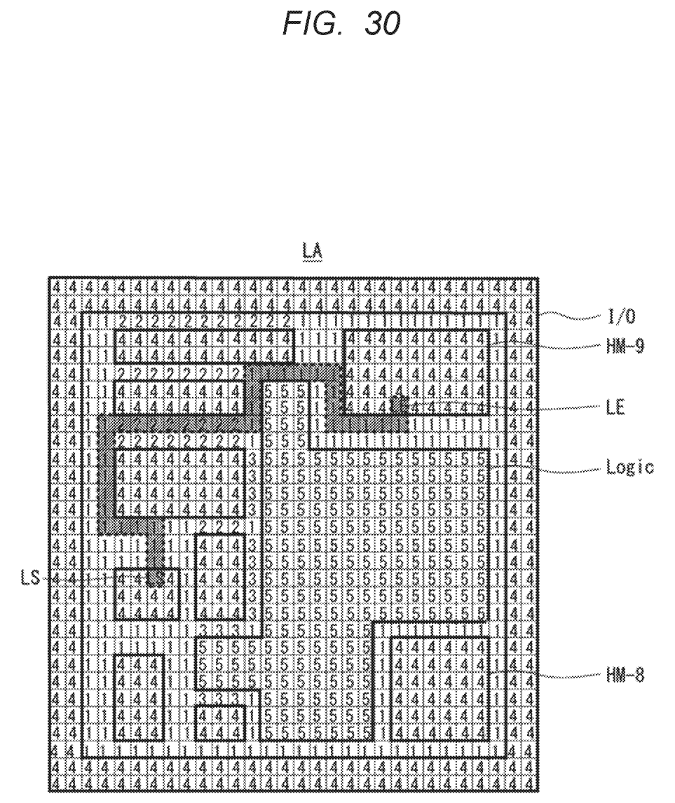

FIG. 30 is a diagram illustrating the wiring path on the layout area LA with wiring costs set above and between each cell in the case of characteristics such as noise resistance being prioritized in the manufacturing apparatus 50 of the semiconductor device according to Embodiment 1. As shown in FIG. 30, calculation unit 54 calculates the wiring cost of the automatically wired wiring path, for example. In the figure, the wiring cost setting figures LCF1 and LCF2 are not set.

The calculation unit 54 sums the wiring costs of the unit grids UL along the wiring path from the starting point SL to the endpoint LE. In cases where characteristics such as noise resistance are prioritized, the wiring cost is set so that wiring is easily arranged around the periphery of the logic cells Logic. Therefore, the wiring path becomes a route that bypasses the hard macro cells HM-1 to 9 and avoids passing above the logic cells Logic. The calculation unit 54 may select the wiring path that implements the wiring route with the minimum total wiring cost.

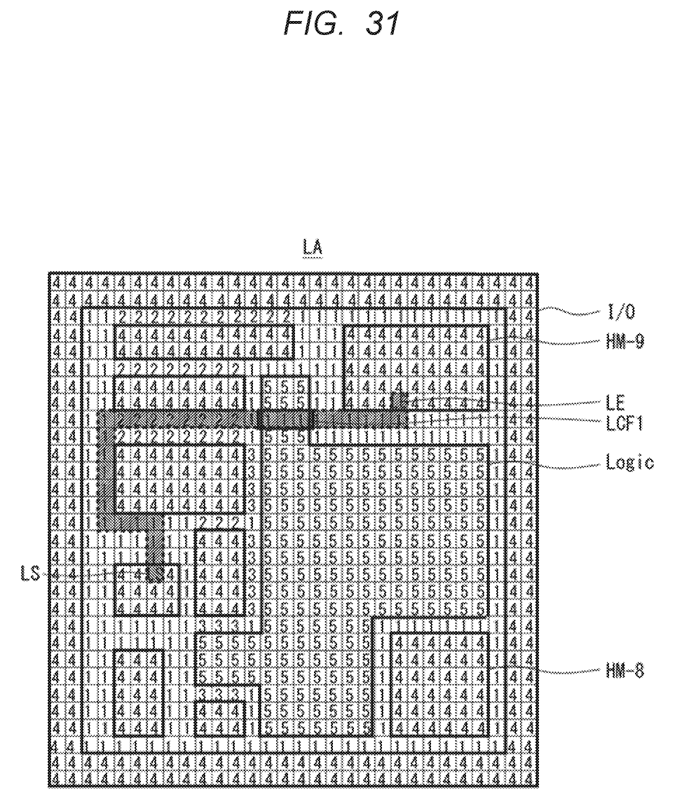

FIG. 31 is a diagram illustrating the wiring path on the layout area LA where the wiring cost is set above and between each cell in the case where characteristics such as noise resistance are prioritized in the manufacturing apparatus 50 of the semiconductor device according to Embodiment 1. As shown in FIG. 31, the wiring cost setting figure LCF1 may be set in the layout area LA. For example, if wiring can be arranged above a part of the logic cells Logic, the wiring cost setting figure LCF1 is arranged on the unit grid UL of such a location. As a result, the wiring cost setting figure LCF1 sets 1 as the wiring cost above a part of the logic cells Logic.

The calculation unit 54 calculates the wiring cost of the unit grid UL along the wiring path from the starting point LS to the endpoint LE. When the wiring cost setting figure LCF1 is arranged, the wiring cost is set so that wiring is easily arranged on the wiring cost setting figure LCF1. Therefore, the wiring path becomes a path that passes above the logic cells Logic where the wiring cost setting figure LCF1 is arranged.

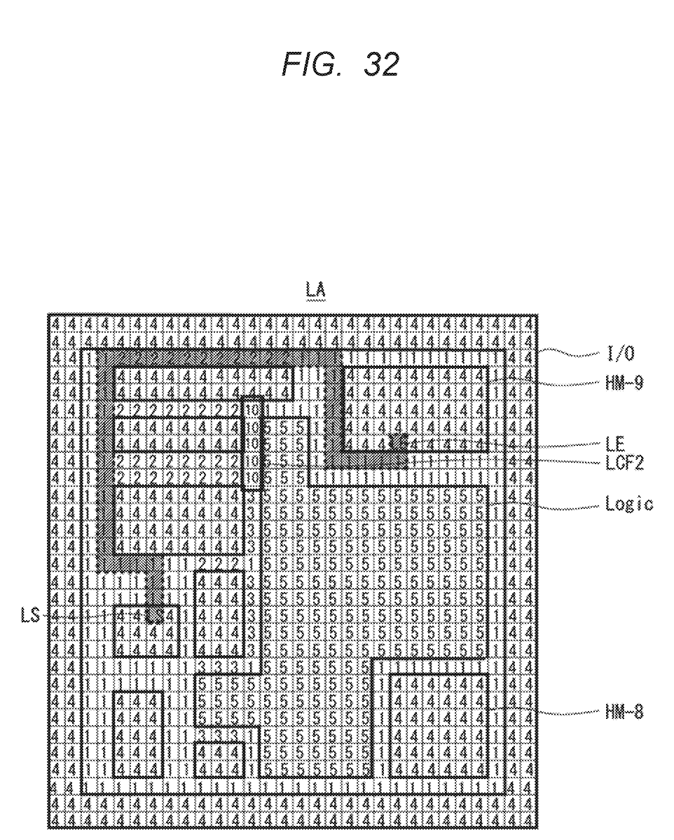

FIG. 32 is a diagram illustrating the wiring path on the layout area LA where the wiring cost is set above and between each cell in the case where characteristics such as noise resistance are prioritized in the manufacturing apparatus 50 of the semiconductor device according to Embodiment 1. As shown in FIG. 32, the wiring cost setting figure LCF2 may be set in the layout area LA. For example, the wiring cost setting figure LCF2 is arranged on the unit grid UL between the hard macros HM-1 and HM-2 and the logic cells Logic. As a result, the wiring cost setting figure LCF2 sets the wiring cost as 10 between the hard macros HM-1 and HM-2 and the logic cells Logic.

The calculation unit 54 calculates the wiring cost of the unit grid UL along the wiring path from the starting point LS to the endpoint LE. When the wiring cost setting figure LCF2 is arranged, the wiring cost is set so that wiring is difficult to arrange on the wiring cost setting figure LCF2. Therefore, the wiring path becomes a route that bypasses the wiring cost setting figure LCF2.

Next, in step S70, if the design constraints are not met (NO), it may return to any of step S51, step S52, or step S53. For example, the step to return may be determined based on the items that do not meet the design constraints. Additionally, the step to return may be determined based on predetermined conditions such as chip size priority or noise resistance priority. Explanations of other steps are included in the description of the comparative example.

Next, the effects of this embodiment will be described. The manufacturing apparatus 50 of the semiconductor device in this embodiment causes the acquisition unit 51 to acquire a wiring cost table. The selection unit 52 selects the wiring cost according to conditions such as chip size priority and noise resistance priority. The setting unit 53 sets the selected wiring cost on the unit grid UL in the layout area LA. Therefore, the calculation unit 54 can select a wiring path with a lower wiring cost from among the wiring paths explored by automatic wiring, etc.

In this way, the manufacturing apparatus 50 of the semiconductor device in this embodiment can automatically explore wiring paths based on the wiring cost set before automatic wiring, thereby reflecting conditions such as chip size priority and noise resistance priority in the layout LA. Thus, it is possible to prevent the enlargement of chip size and the impact of noise in advance.

Moreover, the manufacturing apparatus 50 of the semiconductor device in this embodiment can automatically explore wiring paths considering the complex rules of each cell reflecting conditions such as chip size priority and noise resistance priority. This eliminates the need for manual review of wiring paths.

Furthermore, the manufacturing apparatus 50 of the semiconductor device in this embodiment can automatically place wiring on the desired path in a short time. Therefore, it is possible to confirm the characteristics as wiring at an early stage and minimize the rework of floor plan design. Additionally, by changing the setting values of the wiring cost table, it is easy to control and adjust the wiring paths. Thus, if there is a change in the placement of cells such as hard macro HM, the wiring cost can be automatically reset. This eliminates the need for manual review of wiring paths. This reduces dependency on designers and can suppress variations in wiring quality.

Although the invention made by the present inventor has been specifically described based on the embodiment, the present invention is not limited to the as described above embodiment, and it is needless to say that various modifications can be made without departing from the gist thereof. For example, combinations of the configurations of the comparative example and Embodiment 1 are also within the scope of the technical concept of the embodiment. Also, each setting value in the wiring cost table is illustrative. Furthermore, the following manufacturing method and manufacturing program for semiconductor devices are also within the scope of the technical concept of the embodiment.

### Additional Statement A1

A method for manufacturing a semiconductor device comprising: a step of acquiring a wiring cost table that shows the wiring cost for placing wiring above and between multiple cells arranged in a layout area when designing a semiconductor device, divided according to multiple conditions; a step of selecting the wiring cost from the multiple wiring costs shown in the wiring cost table based on predetermined conditions; a step of setting the selected wiring cost above and between each cell; and a step of calculating the wiring cost of the path where the wiring is placed based on the set wiring cost.

### Additional Statement A2

The step of acquiring the wiring cost table includes a step of creating the wiring cost table and a step of acquiring the created wiring cost table, as described in Additional Statement A1.

### Additional Statement A3

In the step of acquiring the wiring cost table, the wiring cost table is acquired from a storage unit that stores the wiring cost table, as described in Additional Statement A1.

### Additional Statement A4

The layout area includes multiple unit grids, and each cell arranged in the layout area is arranged to include at least one of the unit grids. The unit grids included in each cell indicate the wiring cost when placing wiring above the cell. Each cell arranged in the layout area is arranged to be adjacent to another cell with at least one of the unit grids in between, and the unit grids between each cell indicate the wiring cost for placing wiring between the cells. In the step of setting the selected wiring cost above and between each cell, the selected wiring cost is set for each unit grid in the layout area, as described in Additional Statement A1.

### Additional Statement A5

In the step of creating the wiring cost table, the wiring cost table is created such that the larger the wiring cost, the more difficult it is for wiring to pass, and the smaller the wiring cost, the easier it is for wiring to pass, as described in Additional Statement A2.

### Additional Statement A6

In the step of creating the wiring cost table, the wiring cost table is created such that the larger the wiring cost, the larger the chip size, and the smaller the wiring cost, the smaller the chip size, as described in Additional Statement A2.

### Additional Statement A7

In the step of creating the wiring cost table, the wiring cost table is created such that the larger the wiring cost, the greater the noise resistance, and the smaller the wiring cost, the smaller the noise resistance, as described in Additional Statement A2.

### Additional Statement A8

The semiconductor device includes multiple stacked wiring layers, and in the step of creating the wiring cost table, a wiring cost table is created for each wiring layer where the wiring is placed, indicating the wiring cost, as described in Additional Statement A2.

### Additional Statement A9

In the step of selecting the wiring cost, the wiring cost is selected with at least one of chip size priority and noise resistance priority as predetermined conditions, as described in Additional Statement A1.

### Additional Statement A10

In the step of setting the selected wiring cost above and between each cell, after setting the selected wiring cost above and between multiple cells in the layout area, a first wiring cost setting figure is superimposed on the layout area to make it easier to place the wiring, and the first wiring cost setting figure reduces the wiring cost of the placed portion of the layout area, as described in Additional Statement A1.

### Additional Statement A11

In the step of setting the selected wiring cost above and between each cell, after setting the selected wiring cost above and between multiple cells in the layout area, a second wiring cost setting figure is superimposed on the layout area to make it more difficult to place the wiring, and the second wiring cost setting figure increases the wiring cost of the placed portion of the layout area, as described in Additional Statement A1.

### Additional Statement A12

In the step of setting the selected wiring cost above and between each cell, a default value is set in advance for the unit grid, and the selected wiring cost is overwritten on the default value for each unit grid above and between multiple cells arranged in the layout area, as described in Additional Statement A4.

### Additional Statement A13

In the step of calculating the wiring cost of the wiring path, the wiring cost of the wiring path where the wiring is placed by automatic wiring is calculated based on the wiring cost set in the layout area, as described in Additional Statement A1.

Additional Statement A14

In the step of calculating the wiring cost of the wiring path, a wiring path to be implemented is selected from the wiring path where the wiring is placed by automatic wiring based on the calculated wiring cost, as described in Additional Statement A13.

### Additional Statement A15

The cell includes at least one of an IO buffer cells, a hard macro cell, and a logic cell, as described in Additional Statement A1.

The manufacturing apparatus 50 for semiconductor devices may be an information processing device such as a server or a personal computer. The information processing device as the manufacturing apparatus 50 for semiconductor devices may further include a processor, memory, storage device, and user interface. The storage device stores the processes executed by each configuration of the information processing device as a program. The processor reads the program from the storage device into the memory and executes the program. This allows the processor to realize the functions of each configuration in the information processing device. The user interface may include input devices such as a keyboard, mouse, and imaging device, as well as output devices such as display, printer, and speaker.

Each configuration of the information processing device may be realized by dedicated hardware. Additionally, some or all of the components may be realized by general-purpose or dedicated circuitry, processors, or combinations thereof. These may be configured by a single chip or by multiple chips connected via a bus. Some or all of the components may be realized by a combination of the aforementioned circuitry and programs. Additionally, processors such as a CPU (Central Processing Unit), GPU (Graphics Processing Unit), FPGA (Field-programmable Gate Array), and quantum processors (quantum computer control chips) can be used.

Furthermore, when some or all components of the information processing device are realized by multiple information processing devices or circuits, these devices or circuits may be centrally or distributedly arranged. For example, information processing devices or circuits may be implemented in a form where each is connected via a communication network, such as in a client-server system or cloud computing system. Additionally, the functions of the information processing device may be provided in the form of SaaS (Software as a Service).

### Additional Statement B1

A semiconductor device manufacturing program that causes a computer to execute the steps of obtaining a wiring cost table that shows the wiring costs for placing wiring above and between multiple cells arranged in a layout area when designing a semiconductor device, divided according to multiple conditions; selecting the wiring cost from the multiple wiring costs shown in the wiring cost table based on predetermined conditions; setting the selected wiring cost above and between each cell; and calculating the wiring cost of the path where the wiring is placed based on the set wiring cost.

The semiconductor device manufacturing program may be stored on a non-transitory computer-readable medium or a tangible storage medium. By way of example and not limitation, the computer-readable medium or tangible storage medium includes random-access memory (RAM), read-only memory (ROM), flash memory, solid-state drive (SSD) or other memory technologies, CD-ROM, digital versatile disc (DVD), Blu-ray™ disc or other optical disc storage, magnetic cassette, magnetic tape, magnetic disk storage or other magnetic storage devices. The semiconductor device manufacturing program may be transmitted over a transitory computer-readable medium or communication medium. By way of example and not limitation, a transitory computer-readable medium or communication medium includes electrical, optical, acoustic, or other forms of propagated signals.

What is claimed is:

1. A semiconductor device manufacturing apparatus comprising:
an acquisition circuit configured to obtain a wiring cost table that shows the wiring costs for placing wiring above and between multiple cells arranged in a layout area when designing a semiconductor device, the wiring costs corresponding to multiple conditions;
a selection circuit configured to select the wiring cost from the multiple wiring costs shown in the wiring cost table based on predetermined conditions;
a setting circuit configured to set the selected wiring cost above and between each cell; and
a calculation circuit configured to calculate the wiring cost of the wiring path where the wiring is placed based on the set wiring cost.

2. The semiconductor device manufacturing apparatus according to claim 1,
wherein the acquisition circuit includes a creation circuit configured to create the wiring cost table and obtains the wiring cost table from the creation circuit.

3. The semiconductor device manufacturing apparatus according to claim 1,
wherein the acquisition circuit obtains the wiring cost table from a storage circuit that stores the wiring cost table.

4. The semiconductor device manufacturing apparatus according to claim 1,
wherein the layout area includes multiple unit grids,
wherein each cell arranged in the layout area is arranged to include at least one of the unit grids,
wherein the unit grids included in each cell indicate the wiring costs for placing wiring above the cell,
wherein each cell arranged in the layout area is arranged to be adjacent to another cell with at least one of the unit grids in between,
wherein the unit grids between each cell indicate the wiring cost for placing wiring between the cells, and
wherein the setting circuit sets the selected wiring cost for each unit grid in the layout area.

5. The semiconductor device manufacturing apparatus according to claim 2,
wherein the creation circuit creates the wiring cost table such that the larger the wiring cost, the more difficult it is for wiring to pass, and the smaller the wiring cost, the easier it is for wiring to pass.

6. The semiconductor device manufacturing apparatus according to claim 2,
wherein the creation circuit creates the wiring cost table such that the larger the wiring cost, the larger the chip size, and the smaller the wiring cost, the smaller the chip size.

7. The semiconductor device manufacturing apparatus according to claim 2,
wherein the creation circuit creates the wiring cost table such that the larger the wiring cost, the greater the noise resistance, and the smaller the wiring cost, the smaller the noise resistance.

8. The semiconductor device manufacturing apparatus according to claim 2,
wherein the semiconductor device includes multiple stacked wiring layers, and the creation circuit creates a wiring cost table indicating the wiring cost for each wiring layer where the wiring is placed.

9. The semiconductor device manufacturing apparatus according to claim 1,
wherein the selection circuit selects the wiring cost with at least one of chip size emphasis and noise resistance emphasis as predetermined conditions.

10. The semiconductor device manufacturing apparatus according to claim 1,
wherein the setting circuit, after setting the wiring cost selected by the selection circuit above and between multiple cells in the layout area, superimposes and sets a first wiring cost setting figure in the layout area to make it easier to place the wiring, and
wherein the first wiring cost setting figure reduces the wiring cost of the portion of the layout area where it is placed.

11. The semiconductor device manufacturing apparatus according to claim 1,
wherein the setting circuit, after setting the wiring cost selected by the selection unit above and between multiple cells in the layout area, superimposes and sets a second wiring cost setting figure in the layout area to make it more difficult to place the wiring, and
wherein the second wiring cost setting figure increases the wiring cost of the portion of the layout area where it is placed.

12. The semiconductor device manufacturing apparatus according to claim 4,
wherein the setting circuit sets a default value in advance for the unit grids and overwrites the selected wiring cost for each unit grid above and between multiple cells arranged in the layout area with the default value.

13. The semiconductor device manufacturing apparatus according to claim 1,
wherein the calculation circuit calculates the wiring cost of the wiring path where the wiring is placed by automatic wiring based on the wiring cost set in the layout area.

14. The semiconductor device manufacturing apparatus according to claim 1,
wherein the calculation circuit selects the wiring path to be implemented from the wiring path where the wiring is placed by automatic wiring based on the calculated wiring cost.

15. The semiconductor device manufacturing apparatus according to claim 1,
wherein the cell includes at least one of an IO buffer cell, a hard macro cell, and a logic cell.

16. A semiconductor device manufacturing method comprising the steps of:
(a) obtaining a wiring cost table that shows the wiring costs for placing wiring above and between multiple cells arranged in a layout area when designing a semiconductor device, divided according to multiple conditions;
(b) selecting the wiring cost from the multiple wiring costs shown in the wiring cost table based on predetermined conditions;
(c) setting the selected wiring cost above and between each cell; and
(d) calculating the wiring cost of the wiring path where the wiring is placed based on the set wiring cost.

17. The semiconductor device manufacturing apparatus according to claim 16,
wherein the step of (a) obtaining the wiring cost table includes the step of creating the wiring cost table and the step of obtaining the created wiring cost table.

18. The semiconductor device manufacturing apparatus according to claim 16,
wherein the step of (c) obtaining the wiring cost table, the wiring cost table is obtained from a storage circuit that stores the wiring cost table.

19. The semiconductor device manufacturing apparatus according to claim 16,
wherein the layout area includes multiple unit grids,
wherein each cell arranged in the layout area is arranged to include at least one of the unit grids, with the unit grids included in each cell indicating the wiring cost for placing wiring above the cell,
wherein each cell arranged in the layout area is arranged to be adjacent to another cell with at least one of the unit grids in between,
wherein the unit grids between each cell indicate the wiring cost for placing wiring between the cells,
wherein in the step of setting the selected wiring cost above and between each cell, the selected wiring cost is set for each unit grid in the layout area.

20. The semiconductor device manufacturing apparatus according to claim 17,
wherein in the step of creating the wiring cost table, the wiring cost table is created such that the larger the wiring cost, the more difficult it is for wiring to pass, and the smaller the wiring cost, the easier it is for wiring to pass.
